(19) United States
(12) Patent Application Publication
(10) Pub. No.: US 2020/0235247 A1
(43) Pub. Date: Jul. 23, 2020

(54) SPUTTERING TARGET, OXIDE SEMICONDUCTOR THIN FILM, THIN FILM TRANSISTOR, AND ELECTRONIC DEVICE

(71) Applicant: IDEMITSU KOSAN CO.,LTD., Tokyo (JP)

(72) Inventors: Masashi OYAMA, Sodegaura-shi (JP); Mami ITOSE, Sodegaura-shi (JP)

(73) Assignee: IDEMITSU KOSAN CO.,LTD., Tokyo (JP)

(21) Appl. No.: 16/634,855

(22) PCT Filed: Aug. 1, 2018
(86) PCT No.: PCT/JP2018/028842

§ 371 Date: Jan. 28, 2020

(30) Foreign Application Priority Data
Aug. 1, 2017 (JP) 2017-149398

(51) Int. Cl. H01L 29/786; H01L 29/66; H01L 21/02; H01L 29/24; C23C 14/34; C23C 14/08

(52) U.S. Cl. CPC H01L 29/78693; H01L 29/66969; H01L 21/02592; H01L 21/02565; H01L 27/14616; H01L 29/247; H01L 29/66977; C23C 14/3407; C23C 14/086; H01L 21/02631

(57) ABSTRACT

A sputtering target contains an oxide sinter that contains indium (In) element, tin element (Sn), zinc element (Zn), X element and oxygen, that further contains a spinel structure compound represented by Zn₂SnO₄, and that satisfies a formula (1) representing an atomic ratio of the elements.

0.001≤X/(In+Sn+Zn+X)≤0.05 (1)

In the formula (1), In, Zn, Sn, and X represent contents of the In element, Zn element, Sn element, and X element in the oxide sinter, respectively, and the X element is at least one element selected from Ge, Si, Y, Zr, Al, Mg, Yb and Ga.

### TECHNICAL FIELD

The present invention relates to a sputtering target, an oxide semiconductor thin film, a thin film transistor, and an electronic device.

### BACKGROUND ART

In a typical display such as a liquid crystal display or an organic EL display to be driven by a thin-film transistor (hereinafter, referred to as TFT), a channel layer of TFT is mainly in a form of an amorphous silicon film or crystal silicon film.

However, since a high definition display has been demanded in recent years, an oxide semiconductor has drawn attention as a material used for the channel layer of TFT.

Among the oxide semiconductors, particularly, an amorphous oxide semiconductor (In—Ga—Zn—O, hereinafter, abbreviated as “IGZO”) formed of indium, gallium, zinc, and oxygen, which is disclosed in Patent Literature 1, has been favorably used since the IGZO has a high carrier mobility. However, the IGZO contains In and Ga as materials, which entails a high material cost.

In order to reduce the material cost, Zn—Sn—O (hereinafter, abbreviated as “ZTO”) (Patent Literature 2) or In—Sn—Zn—O (hereinafter, abbreviated as “ITZO”) (Patent Literature 3) in which Sn is added in place of Ga in IGZO has been proposed. Among the above, since ITZO exhibits an extremely high mobility as compared with IGZO, ITZO has been noted as a material second to IGZO.

However, ITZO has a large thermal expansion coefficient and a low thermal conductivity among the materials used for the oxide semiconductor. Accordingly, a sputtering target formed of ITZO is likely to be cracked due to thermal stress applied when the sputtering target is bonded to a Cu- or Ti-made backing plate and sputtered.

Here, Patent Literature 3 proposes improving a strength of an oxide sinter by containing a hexagonal laminar compound represented by In₂O₃(ZnO)ₘ and a spinel structure compound represented by Zn₂SnO₄ in the oxide sinter and by setting an aspect ratio of the hexagonal laminar compound represented by In₂O₃(ZnO)ₘ to be 3 or more.

Patent Literature 4 discloses that a sputtering target can contain aluminum in addition to the hexagonal laminar compound and the spinel structure compound as long as an advantage of the invention is not hampered.

Patent Literature 5 discloses a sputtering target in a form of an oxide containing an indium (In) element, tin (Sn) element, zinc (Zn) element and aluminum (Al) element, the sputtering target containing a homologous structure compound represented by In₂O₃(ZnO)ₙ (n is in a range from 2 to 20) and the spinel structure compound represented by Zn₂SnO₄.

### CITATION LIST

### Patent Literature(S)

Patent Literature 1: International Publication No. WO 2012/067036

Patent Literature 2: JP 2017-36497 A

Patent Literature 3: International Publication No. WO 2013/179676

Patent Literature 4: International Publication No. WO 2007/037191

Patent Literature 5: JP 2014-98204 A

### SUMMARY OF THE INVENTION

### Problem(s) to be Solved by the Invention

However, the ITZO sputtering targets of Patent Literatures 3 to 5 have disadvantages below.

The sputtering target disclosed in Patent Literature 3 requires 200 Wh or more of a total power for mixing and pulverizing starting material powders in order to set the aspect ratio of the hexagonal laminar compound represented by In₂O₃(ZnO)ₘ to be 3 or more. At a large amount of the starting material powders for mass production or the like, power is not evenly transmitted all over the starting material powders when mixing or pulverizing the starting material powders, and the hexagonal laminar compound with the aspect ratio of 3 or more is not evenly deposited in a sinter to cause an uneven strength of the sputtering target.

Patent Literatures 4 and 5 aim to provide the sputtering target having a high density and a low resistivity, but fail to suggest the strength of the sputtering target. Accordingly, the sputtering targets disclosed in Patent Literatures 4 and 5 are not structured so as to prevent occurrence of cracks at sputtering.

In light of the above disadvantages, an object of the present invention is to provide a sputtering target with a high strength capable of preventing occurrence of cracks when the sputtering target is bonded to a backing plate and sputtered.

### Means for Solving the Problem(s)

The invention provides a sputtering target, an oxide semiconductor thin film, a thin film transistor, and an electronic device below.

[1]. According to an aspect of the invention, a sputtering target contains an oxide sinter having indium (In) element, tin (Sn) element, zinc (Zn) element, X element and oxygen, the oxide sinter having a spinel structure compound represented by Zn₂SnO₄ and satisfying a formula (1) representing an atomic ratio of the elements,

0.001≤X/(In+Sn+Zn+X)≤0.05 (1).

In the formula (1), In, Zn, Sn, and X represent contents of the In element, Zn element, Sn element, and X element in the oxide sinter, respectively, and the X element is at least one element selected from Ge, Si, Y, Zr, Al, Mg, Yb and Ga.

[2]. In the sputtering target of the above aspect, the atomic ratio represented by the formula (1) of the oxide sinter is in a range from 0.003 to 0.03.
[3]. In the sputtering target of the above aspect, the oxide sinter satisfies a formula (2) below,

0.40≤Zn/(In+Sn+Zn)≤0.80 (2).

[4]. In the sputtering target of the above aspect, the oxide sinter satisfies a formula (3) below,

0.15≤Sn/(Sn+Zn)≤0.40 (3).

[5]. In the sputtering target of the above aspect, the oxide sinter satisfies a formula (4) below,

0.10≤In/(In+Sn+Zn)≤0.35 (4).

[6]. In the sputtering target of the above aspect, the oxide sinter further contains a hexagonal laminar compound represented by In₂O₃(ZnO)ₘ in which m is in a range from 2 to 7.
[7]. In the sputtering target of the above aspect, the oxide sinter exhibits an average deflective strength of 150 MPa or more.
[8]. In the sputtering target of the above aspect, a Weibull coefficient of an average deflective strength of the oxide sinter is 7 or more.
[9]. In the sputtering target of the above aspect, the oxide sinter has an average crystal grain size of 10 μm or less, and a difference between an average crystal grain size of a hexagonal laminar compound and an average crystal grain size of the spinel structure compound is 1 μm or less.
[10]. Tin the sputtering target of the above aspect, the oxide sinter has an average crystal grain size of 10 μm or less, and a difference between an average crystal grain size of a Bixbyite structure compound and an average crystal grain size of the spinel structure compound is 1 μm or less.
[11]. According to another aspect of the invention, an oxide semiconductor thin-film contains indium (In) element, tin (Sn) element, zinc (Zn) element, X element and oxygen and satisfies a formula (1A) representing an atomic ratio of the elements,

0.001≤X/(In+Sn+Zn+X)≤0.05 (1A)

In the formula (1A), In, Zn, Sn, and X represent contents of the In element, Zn element, Sn element, and X element in the oxide semiconductor thin-film, respectively, and the X element is at least one element selected from Ge, Si, Y, Zr, Al, Mg, Yb and Ga.

[12]. According to still another aspect of the invention, a thin-film transistor includes the oxide semiconductor film according to the above aspect.
[13]. According to a further aspect of the invention, an electronic device includes the thin-film transistor according to the above aspect.

The above aspects of the invention can provide a sputtering target with a high strength capable of preventing occurrence of cracks when the sputtering target is bonded to a backing plate and sputtered.

### BRIEF DESCRIPTION OF DRAWING(S)

FIG. 1A is a perspective view showing a shape of a target according to an exemplary embodiment of the invention.

FIG. 1B is a perspective view showing a shape of another target according to an exemplary embodiment of the invention.

FIG. 1C is a perspective view showing a shape of still another target according to an exemplary embodiment of the invention.

FIG. 1D is a perspective view showing a shape of a further target according to an exemplary embodiment of the invention.

FIG. 2 is a vertical cross section showing a thin-film transistor according to an exemplary embodiment of the invention.

FIG. 3 is a vertical cross section showing another thin-film transistor according to an exemplary embodiment of the invention.

FIG. 4 is a vertical cross section showing a quantum-tunneling field-effect transistor according to an exemplary embodiment of the invention.

FIG. 5 is a vertical cross section showing a quantum-tunneling field-effect transistor according to another exemplary embodiment.

FIG. 6 is a photograph taken by a TEM (Transmission Electron Microscope) showing a silicon oxide layer between a p-type semiconductor layer and an n-type semiconductor layer shown in FIG. 5.

FIG. 7A is a vertical cross section showing a step in a production process of the quantum-tunneling field-effect transistor.

FIG. 7B is a vertical cross section showing a next step in the production process of the quantum-tunneling field-effect transistor.

FIG. 7C is a vertical cross section showing a next step in the production process of the quantum-tunneling field-effect transistor.

FIG. 7D is a vertical cross section showing a next step in the production process of the quantum-tunneling field-effect transistor.

FIG. 7E is a vertical cross section showing a next step in the production process of the quantum-tunneling field-effect transistor.

FIG. 8A is a top plan showing a display using the thin-film transistor according to the exemplary embodiment of the invention.

FIG. 8B illustrates a circuit of a pixel unit applicable to a pixel of a VA liquid crystal display.

FIG. 8C illustrates a circuit of a pixel unit in a display using an organic EL device.

FIG. 9 illustrates a circuit of a pixel unit of a solid-state image sensor using a thin-film transistor according to an exemplary embodiment of the invention.

FIG. 10 illustrates a relationship between a content of an X element and an average deflective strength in an oxide sinter with In:Sn:Zn=30:15:55 in Examples.

FIG. 11 illustrates a relationship between the content of the X element and an relative density in the oxide sinter with In:Sn:Zn=30:15:55 in Examples.

FIG. 12 illustrates a relationship between the content of the X element and a bulk resistivity in the oxide sinter with In:Sn:Zn=30:15:55 in Examples.

FIG. 13 illustrates a relationship between the content of the X element oxide and a Weibull coefficient in the sintered with In:Sn:Zn=30:15:55 in Examples.

FIG. 14 illustrates a relationship between the content of the X element and an average crystal grain size in the oxide sinter with In:Sn:Zn=30:15:55 in Examples.

FIG. 15 illustrates an average deflective strength in cases where the X element is contained at 0.1 atom % in a form of GeO₂, SiO₂, Y₂O₃, ZrO₂, Al₂O₃, MgO or Yb₂O in the oxide sinter and a case where no X element is contained in the oxide sinter.

### DESCRIPTION OF EMBODIMENT(S)

Exemplary embodiment(s) of the invention will be described below with reference to attached drawing(s). It should however be noted that it is easily understood by those skilled in the art that the exemplary embodiment(s) may be modified in various manners, as long as such modification and details are compatible with an object and scope of the invention. Accordingly, the scope of the invention should by no means be interpreted to be restricted to the disclosure in the exemplary embodiment(s) below.

Further, in the drawing(s), a size, a layer thickness, or a region is sometimes exaggerated for clarification. Thus, the scale of the drawing(s) is not necessarily limiting. It should be noted that the drawing(s) schematically shows an ideal example, and illustrated shape(s) and/or value(s) are not limited to those shown in the drawing(s).

Further, ordinals such as “first,” “second,” and “third,” used in the specification are attached for avoiding confusion between components, and are not numerically limiting.

In the specification and the like, the term “electrically connected” encompasses a connection through “an object of some electric action.” The “object of some electric action” is not limited to specific object as long as such an object allows communication of electric signals between connected components. Examples of the “object of some electric action” include an electrode, a line, a switching element such as a transistor, a resistor, an inductor, a capacitor, and devices having other function(s).

In the specification and the like, the term “film” or “thin-film” is sometimes interchangeable with the term “layer.”

In the specification and the like, a source and a drain of a transistor are sometimes interchanged when, for instance, a transistor of different polarity is used or a direction of a current is changed during an operation of a circuit. Accordingly, the terms “source” and “drain” in the specification and the like are interchangeable.

### Sputtering Target

A sputtering target according to an exemplary embodiment of the invention (hereinafter, sometimes simply referred to as the sputtering target of the exemplary embodiment) contains an oxide sinter.

The sputtering target of the exemplary embodiment is obtained, for instance, by cutting a bulk of an oxide sinter into a suitable shape as the sputtering target and polishing the cut piece. Alternatively, the sputtering target can also be obtained by bonding a sputtering target material, which is obtained by grinding and polishing a bulk of an oxide sinter, to a backing plate. Another sputtering target of the exemplary embodiment is in a form of an oxide sinter alone.

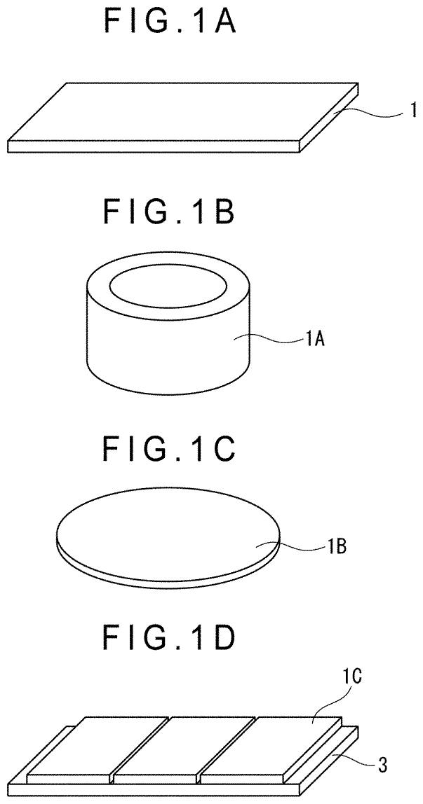

The shape of the oxide sinter is not particularly limited. For instance, the oxide sinter may be a plate as shown in FIG. 1A (item 1) or a hollow cylinder as shown in FIG. 1B (item 1A). When the oxide sinter is plate-shaped, the oxide sinter may be rectangular in a plan view as shown in FIG. 1A (item 1) or circular in a plan view as shown in FIG. 1C (item 1B). The oxide sinter may be a single-piece molding or may be a multiple-division component including a plurality of divided oxide sinters (item 1C) fixed on a backing plate 3 as shown in FIG. 1D.

The backing plate 3 is a holder/cooler for the oxide sinter. A material of the backing plate 3, which is not particularly limited, is exemplified by Cu, Ti, and SUS.

The oxide sinter of the exemplary embodiment contains indium (In) element, tin (Sn) element, zinc (Zn) element, X element and oxygen. As long as the advantages of the invention are not hampered, the oxide sinter may contain another metal element(s) in addition to the above indium (In) element, tin (Sn) element, zinc (Zn) element, and X element, may consist essentially of the indium (In) element, tin (Sn) element, zinc (Zn) element, and X element, or may consist solely of the indium (In) element, tin (Sn) element, zinc (Zn) element, and X element.

Herein, the term “essentially” means that the indium (In) element, tin (Sn) element, zinc (Zn) element and X element account for 95 mass % to 100 mass % (preferably 98 mass % to 100 mass %) of the metal elements of the oxide sinter. The oxide sinter of the exemplary embodiment may contain inevitable impurities in addition to In, Sn, Zn and Al as long as the advantages of the invention are not hampered. The inevitable impurities herein mean an element(s) that is not intentionally added but are mixed in a material or during a production process.

The X element is at least one element selected from germanium (Ge) element, silicon (Si) element, yttrium (Y) element, zirconium (Zr) element, aluminum (Al) element, magnesium (Mg) element, ytterbium (Yb) element, and gallium (Ga) element.

Examples of the inevitable impurities include alkali metal, alkaline earth metal (e.g. Li, Na, K, Rb, Ca, Sr, Ba), hydrogen (H) element, boron (B) element, carbon (C) element, nitrogen (N) element, fluorine (F) element, and chlorine (Cl) element.

The oxide sinter of the exemplary embodiment satisfies a formula (1) representing an atomic ratio of the elements.

0.001≤X/(In+Sn+Zn+X)≤0.05 (1)

In the formula (1), In, Zn, Sn, and X represent contents of the In element, Zn element, Sn element, and X element in the oxide sinter, respectively, and the X element is at least one element selected from Ge, Si, Y, Zr, Al, Mg, Yb and Ga.

In the exemplary embodiment, an average deflective strength of the oxide sinter can be sufficiently high by setting a content ratio of the X element in the oxide sinter within the range of the formula (1).

The X element is preferably silicon (Si) element, aluminum (Al) element, magnesium (Mg) element, ytterbium (Yb) element, and gallium (Ga) element, more preferably silicon (Si) element, aluminum (Al) element, and gallium (Ga) element. The aluminum (Al) element and gallium (Ga) element are particularly preferable since each element has a stable composition in a form of an oxide as the starting material and significantly improves the average deflective strength.

At X/(In+Sn+Zn+X) being 0.001 or more, deterioration in the strength of the sputtering target can be prevented. At X/(In+Sn+Zn+X) being 0.05 or less, an oxide semiconductor thin-film formed of the sputtering target containing the oxide sinter at this ratio can be easily etched by weak acid such as oxalic acid. Further, deterioration in the TFT characteristics, particularly, a decrease in the mobility can be prevented. X/(In+Sn+Zn+X) is preferably in a range from 0.001 to 0.05, more preferably in a range from 0.003 to 0.03, further preferably in a range from 0.005 to 0.01, particularly preferably in a range from 0.005 to less than 0.01.

The oxide sinter of the exemplary embodiment may contain a single X element or two or more X elements. When two or more X elements are contained, X in the formula (1) is defined as a total of the atomic ratios of the X elements.

An existence form of the X element in the oxide sinter is not particularly defined. Examples of the existence form of the X element in the oxide sinter include a form of existing as an oxide, a form of a solid solution, and a form of segregation in a grain boundary.

In the oxide sinter of the exemplary embodiment, a bulk resistivity of the sputtering target can be sufficiently low by setting the content ratio of the X element in the oxide sinter within the range of the formula (1). The bulk resistivity of the sputtering target of the exemplary embodiment is preferably 50 mΩcm or less, more preferably 25 mΩcm or less, further preferably 10 mΩcm or less, still further preferably 5 mΩcm or less, particularly preferably 3 mΩcm or less. When the bulk resistivity is 50 mΩcm or less, a film can be stably formed by direct-current sputtering.

A value of the bulk resistivity can be measured in accordance with a four-probe method (JIS R 1637:1998) using a known resistivity meter. Preferably, values of the bulk resistivity are measured at about nine points and an average of the values is defined as the value of the bulk resistivity.

When the oxide sinter has a quadrangular surface in a planar view, preferably, the quadrangular surface is divided into nine quadrangles each having an equal area and nine centers of the nine quadrangles are defined as the measurement points.

When the oxide sinter has a circular surface in a planar view, preferably, a square inscribed in the circular surface is divided into nine squares each having an equal area and nine centers of the nine squares are defined as the measurement points.

More preferably, the oxide sinter of the exemplary embodiment satisfies at least one of formulae (2) to (4) below representing the atomic ratios of the elements, respectively.

0.40≤Zn/(In+Sn+Zn)≤0.80 (2)

0.15≤Sn/(Sn+Zn)≤0.40 (3)

0.10≤In/(In+Sn+Zn)≤0.35 (4)

In the formulae (2) to (4), In, Zn, and Sn represent contents of the In element, Zn element, and Sn element in the oxide sinter, respectively.

At Zn/(In+Sn+Zn) being 0.4 or more, a spinel phase is likely to be generated in the oxide sinter, thereby easily achieving characteristics as a semiconductor. At Zn/(In+Sn+Zn) being 0.80 or less, deterioration in the strength of the oxide sinter, which is caused by abnormal grain growth of the spinel phase, can be prevented. At Zn/(In+Sn+Zn) being 0.80 or less, a decrease in the mobility of the oxide semiconductor thin-film can be prevented. Zn/(In+Sn+Zn) is more preferably in a range from 0.50 to 0.70.

At Sn/(Sn+Zn) being 0.15 or more, deterioration in the strength of the oxide sinter, which is caused by abnormal grain growth of the spinel phase, can be prevented. At Sn/(Sn+Zn) being 0.40 or less, agglomeration of tin oxide in the oxide sinter, which causes abnormal electrical discharge during sputtering, can be prevented. At Sn/(Sn+Zn) being 0.40 or less, the oxide semiconductor thin-film formed using the sputtering target can be easily etched by weak acid such as oxalic acid. At Sn/(Sn+Zn) being 0.15 or more, an etching speed can be prevented from being excessively high to facilitate controlling the etching. Sn/(Sn+Zn) is more preferably in a range from 0.15 to 0.35.

At In/(In+Sn+Zn) being 0.1 or more, the obtained sputtering target can have a low bulk resistivity. Moreover, at In/(In+Sn+Zn) being 0.1 or more, a mobility of the oxide semiconductor thin-film can be prevented from being excessively lowered. At In/(In+Sn+Zn) being 0.35 or less, the film formed by sputtering can be prevented from becoming a conductor to easily achieve the characteristics as the semiconductor. In/(In+Sn+Zn) is more preferably in a range from 0.10 to 0.30.

The respective atomic ratios of the elements of the oxide sinter are controllable by contents of starting materials of the respective elements. The respective atomic ratios of the elements can be obtained by performing quantitative analysis on the contained elements through ICP-AES (Inductively Coupled Plasma-Atomic Emission Spectrometry).

The oxide sinter of the exemplary embodiment preferably contains a spinel structure compound represented by Zn₂SnO₄, more preferably contains the spinel structure compound represented by Zn₂SnO₄ and a hexagonal laminar compound represented by In₂O₃(ZnO)ₘ in which m is an integer from 2 to 7. In In₂O₃(ZnO)ₘ, m is an integer from 2 to 7, preferably from 3 to 5. It should be noted that the spinel structure compound herein is sometimes referred to as a spinel compound.

At m of 2 or more, the compound has a hexagonal laminar structure. At m of 7 or less, the bulk resistivity of the oxide sinter is lowered.

The hexagonal laminar compound formed of indium oxide and zinc oxide is a compound showing an X ray diffraction pattern belonging to a hexagonal laminar compound in a measurement in accordance with an X ray diffraction method. The hexagonal laminar compound contained in the oxide sinter is represented by In₂O₃(ZnO)ₘ.

The oxide sinter of exemplary embodiment may contain the spinel structure compound represented by Zn₂SnO₄ and a Bixbyite structure compound represented by In₂O₃.

### Average Crystal Grain Size

An average crystal grain size of the oxide sinter of the exemplary embodiment is preferably 10 μm or less, more preferably 8 μm or less in terms of prevention of abnormal electrical discharge and easy production of the oxide sinter. At the average crystal grain size being 10 μm or less, abnormal electrical discharge caused by a grain boundary can be prevented. The lower limit of the average crystal grain size of the oxide sinter, which is not particularly limited, is preferably 1 μm or more in terms of the easy production of the oxide sinter.

The average crystal grain size is adjustable by selecting the starting material and changing production conditions. Specifically, the starting material to be used has a small average grain size, preferably, of 1 μm or less. Further, as a sintering temperature becomes higher or a sintering time becomes longer during sintering, the average crystal grain size tends to become larger.

The average crystal grain size can be measured as follows.

A surface of the oxide sinter is polished. When the oxide sinter has a quadrangular surface in a planar view, the quadrangular surface is divided into 16 quadrangles each having an equal area. At each of centers of the 16 quadrangles, grains observed within a frame of 1000 magnifications (80 μm×125 μm) are measured in terms of the crystal grain size. The crystal grain sizes measured in each of the frames at the 16 centers are averaged and, finally, the obtained averages of the 16 centers are averaged and defined as the average crystal grain size.

When the oxide sinter has a circular surface in a planar view, after the surface of the oxide sinter is polished, a square inscribed in the circular surface is divided into 16 squares each having an equal area. At each of centers of the 16 squares, grains observed within a frame of 1000 magnifications (80 μm×125 μm) are measured in terms of the crystal grain size. The crystal grain sizes measured in each of the frames at the 16 centers are averaged and, finally, the obtained averages of the 16 centers are averaged.

As for the crystal grain having the aspect ratio of less than 2, the crystal grain size is determined by measuring a circle equivalent diameter in accordance with JIS R 1670:2006. In a measurement step of the circle equivalent diameter, specifically, a circle ruler is put in contact with a measurement target grain in a microstructure photograph, and a diameter of the measurement target grain, which is equivalent to an area of the measurement target grain, is read. As for the crystal grain having the aspect ratio of 2 or more, the longest diameter and the shortest diameter of the grain are averaged and the obtained average is defined as a grain size of the grain. Crystal grains are observable with a scan electron microscope (SEM). The hexagonal laminar compound, the spinel compound, and the Bixbyite structure compound are confirmable according to a method described in later-described Examples.

When the oxide sinter of the exemplary embodiment contains the hexagonal laminar compound and the spinel compound, a difference between an average crystal grain size of the hexagonal laminar compound and an average crystal grain size of the spinel compound is preferably 1 μm or less. With the respective average crystal grain sizes set as the above, the strength of the oxide sinter is improvable.

It is more preferable that the oxide sinter of the exemplary embodiment has the average crystal grain size of 10 μm or less, and the difference between the average crystal grain size of the hexagonal laminar compound and the average crystal grain size of the spinel compound is 1 μm or less.

When the oxide sinter of the exemplary embodiment contains the Bixbyite structure compound and the spinel compound, a difference between an average crystal grain size of the Bixbyite structure compound and the average crystal grain size of the spinel compound is preferably 1 μm or less. With the respective average crystal grain sizes set as the above, the strength of the oxide sinter is improvable.

It is more preferable that the oxide sinter of the exemplary embodiment has the average crystal grain size of 10 μm or less, and the difference between the average crystal grain size of the Bixbyite structure compound and the average crystal grain size of the spinel compound is 1 μm or less.

A relative density of the oxide sinter of the exemplary embodiment is preferably 95% or more, more preferably 96% or more. The oxide sinter having the relative density of 95% or more imparts a high mechanical strength and an excellent conductivity to the sputtering target. Accordingly, when this sputtering target applied to an RF magnetron sputtering device or a DC magnetron sputtering device is sputtered, stability of plasma discharge can be enhanced. The relative density of the oxide sinter is represented by a percentage of an actually measured density of the oxide sinter relative to a theoretical density thereof, which is calculated from densities inherent to indium oxide, zinc oxide, tin oxide and oxide of the X element and a composition ratio thereof.

The average deflective strength of 150 MPa or more of the oxide sinter of the exemplary embodiment can prevent occurrence of cracking on the sputtering target caused by high-temperature loads applied when, for instance, the sputtering target is bonded to the backing plate and sputtered. Herein, in accordance with JIS R 1601:2008, a prismatic test piece is placed across two supports spaced from each other at a 30-mm interval, and a load is applied to a press piece while the press piece is put on a central portion of the test piece. An average of loads applied when 30 test pieces are broken (three-point flexural strength) is defined as the average deflective strength.

The average deflective strength of the oxide sinter of the exemplary embodiment is preferably 180 MPa or more, more preferably 210 MPa or more, further preferably 230 MPa or more, particularly preferably 250 MPa or more.

A Weibull coefficient of the average deflective strength of the oxide sinter of the exemplary embodiment is preferably 7 or more, more preferably 10 or more, further preferably 15 or more. The Weibull coefficient of the average deflective strength of the oxide sinter of the exemplary embodiment is preferably 7 or more since the strength of the oxide sinter is less varied as the Weibull coefficient is larger. In accordance with a statistical analysis method defined in JIS R 1625:2010, deflective strength is plotted on a Weibull probability axis (hereinafter, referred to as “Weibull plot”). The Weibull coefficient is obtained from an inclination of the Weibull plot.

The oxide sinter of the exemplary embodiment is producible through a mixing step of mixing an indium starting material, zinc starting material, tin starting material and X element starting material, a molding step of mold the starting material mixture, a sintering step of sintering the molded substance, and an annealing step of annealing the obtained sinter as needed. The above steps will be specifically described below.

### (1) Mixing Step

In the mixing step, firstly, the starting materials are prepared.

Any compound or metal containing In is usable as the In starting material.

Any compound or metal containing Zn is usable as the Zn starting material.

Any compound or metal containing Zn is usable as the Sn starting material.

Any compound or metal containing X is usable as the X starting material.

The In starting material, Zn starting material, Sn starting material, and X element starting material are preferably in a form of oxides.

The starting materials that are indium oxide, zinc oxide, tin oxide, X element oxide and the like are desirably highly pure. A purity of each of the starting materials is 99 mass % or more, preferably 99.9 mass % or more, more preferably 99.99 mass % or more. Use of the highly pure starting materials is preferable since the obtained sinter has a dense structure, whereby the sputtering target including the sinter has a low volume resistivity.

An average grain size of a primary grain of each of the metal oxides as the starting materials is preferably in a range from 0.01 μm to 10 μm, more preferably from 0.05 μm to 5 μm, further preferably from 0.1 μm to 5 μm. At the average grain size being 0.01 μm or more, the metal oxides are unlikely to agglomerate. At the average grain size being 10 μm or less, the metal oxides are sufficiently mixed to provide a sinter having a dense structure. The average grain size is measured in accordance with a BET method.

The starting materials may be added with polyvinyl alcohol, or binder such as vinyl acetate.

The starting materials may be mixed using a typical mixer such as a ball mill, jet mill, and bead mill.

The mixture obtained in the mixing step may be immediately subjected to the forming step or may be prebaked before the forming step. At the prebaking, the mixture is usually baked at a temperature from 700 degrees C. to 900 degrees C. for one hour to five hours.

By pelletizing the mixture of the starting material powders subjected to no prebaking or the prebaked mixture, fluidity and filling capability of the mixture, which are required at the subsequent molding step, are improved. A spray dryer and the like are usable for the pellitizing. An average grain size of a secondary grain formed by the pellitizing is preferably in a range from 1 μm to 100 μm, more preferably from 5 μm to 100 μm, further preferably from 10 μm to 100 μm. It should be noted that, since the grains of the prebaked mixture are mutually bonded, the grains are pulverized before being pelletized.

### (2) Molding Step

The powders or pelletized substance of the starting materials are molded by a method such as die press molding, casting molding or injection molding at the molding step. In order to obtain a sinter having a high sindered density as the sputtering target, it is preferable that the powders or pelletized substance of the starting materials are preliminarily molded by the die press molding or the like at the molding step, and subsequently, are further compacted by cold isostatic press molding or the like.

### (3) Sintering Step

In the sintering step, a typical sintering method such as pressureless sintering, hot press sintering, or hot isostatic press sintering is usable. The sintering temperature is preferably in a range from 1200 degrees C. to 1600 degrees C., more preferably from 1250 degrees C. to 1550 degrees C., further preferably from 1300 degrees C. to 1500 degrees C. At the sintering temperature of 1200 degrees C. or more, a sufficient sintering density is obtained and the bulk resistivity of the sputtering target also can be lowered. At the sintering temperature of 1600 degrees C. or less, sublimation of zinc oxide at the sintering can be prevented. A temperature increase rate during the sintering is preferably 0.1 degrees C./min to 3 degrees C./min from the room temperature to the sintering temperature. In a course of increasing the temperature, the temperature may be kept in a range from 700 degrees C. to 800 degrees C. for one hour to ten hours and again raised to the sintering temperature.

The sintering time, although depending on the sintering temperature, is preferably in a range from 1 hours to 50 hours, more preferably from 2 hours to 30 hours, further preferably from 3 hours to 20 hours. The sintering may be performed in an atmosphere of air or oxygen gas, which may be added with a reducing gas such as hydrogen gas, methane gas or carbon monoxide gas or an inert gas such as argon gas or nitrogen gas.

### (4) Annealing Step

In the annealing step, which is not necessarily requisite though, the atmosphere temperature is usually kept from 700 degrees C. to 1100 degrees C. for one hour to five hours. In the annealing step, the sinter may be cooled and then the atmosphere temperature is again raised to be annealed, or may be annealed while the sintering temperature is lowered. The annealing may be performed at the atmosphere of air or oxygen gas, which may be added with a reducing gas such as hydrogen gas, methane gas or carbon monoxide gas or an inert gas such as argon gas or nitrogen gas.

The sinter obtained through the above steps (1) to (4) is cut into an appropriate shape and a surface of the sinter is polished as required to obtain a final sputtering target.

Specifically, the sinter is cut into a shape suitable for attachment to a sputtering device, whereby the sinter is provided as a sputtering target material (sometimes referred to as a target material). The target material is bonded to a backing plate to provide a sputtering target.

When the sinter is used as the target material, surface roughness Ra of the sinter is preferably 0.5 μm or less. A method of adjusting the surface roughness Ra of the sinter is exemplified by grinding the sinter with a surface grinder.

The surface of the sputtering target material is preferably finished with a diamond grinding stone #200 to #1,000, particularly preferably with a diamond grinding stone #400 to #800. By using the diamond grinding stone #200 or higher, or #1,000 or less, cracking of the sputtering target material can be prevented.

The sputtering target material preferably has a non-directional ground surface having the surface roughness Ra of 0.5 μmn or less. The sputtering target material having the non-directional ground surface having the surface roughness Ra of 0.5 μmn or less can prevent abnormal electrical discharge and occurrence of particles.

Finally, the obtained sputtering target material is cleaned. An air blower or running water is usable for cleaning. When the air blower is used for removing a foreign substance, air is sucked with a dust catcher opposite a nozzle of the air blower, whereby the foreign substance is more effectively removable.

It should be noted that ultrasonic cleaning may further be performed in view of the limited effects of the cleaning by the air blower and running water. The ultrasonic cleaning is effectively performed with oscillation at multiple frequencies ranging from 25 kHz to 300 kHz. For instance, twelve waves of different frequencies ranging from 25 kHz to 300 kHz in 25 kHz increments are preferably applied for the ultrasonic cleaning.

A thickness of the sputtering target material is usually in a range from 2 mm to 20 mm, preferably from 3 mm to 12 mm, more preferably from 4 mm to 9 mm, particularly preferably from 4 mm to 6 mm.

The sputtering target can be obtained by bonding the sputtering target material, which is obtained through the above steps and treatments, to the backing plate. Alternatively, a plurality of sputtering target materials may be bonded to a single backing plate to provide substantially a single sputtering target.

The sputtering target of the exemplary embodiment can have the relative density of 98% or more and the bulk resistivity of 5 mΩcm or less according to the above production method, and can prevent occurrence of abnormal electrical discharge during the sputtering. Moreover, the sputtering target of the exemplary embodiment can form a high-quality oxide semiconductor thin-film efficiently, inexpensively and energy-savingly.

According to the exemplary embodiment, the sputtering target thus contains the oxide sinter containing In, Sn, Zn, X, oxygen, and the balance being inevitable impurities, the oxide sinter satisfying the formula (1) representing the atomic ratio of the elements.

Accordingly, the sputtering target can prevent occurrence of cracking when the sputtering target is bonded to the backing plate and sputtered.

### Oxide Semiconductor Thin-Film

Next, an oxide semiconductor thin-film according to the exemplary embodiment will be described below.

The oxide semiconductor thin-film of the exemplary embodiment contains indium (In) element, tin (Sn) element, zinc (Zn) element, X element and oxygen, and satisfies a formula (1A) below representing an atomic ratio of the elements.

0.001≤X/(In+Sn+Zn+X)≤0.05 (1A)

In the formula (1A), In, Zn, Sn, and X represent contents of the In element, Zn element, Sn element, and X element in the oxide semiconductor thin-film, respectively, and the X element is at least one element selected from Ge, Si, Y, Zr, Al, Mg, Yb and Ga.

The oxide semiconductor thin-film of the exemplary embodiment is producible through the sputtering process using the sputtering target. The atomic ratio composition of the oxide semiconductor thin-film obtained through the sputtering process reflects the atomic ratio composition of the oxide sinter in the sputtering target.

When the sputtering target of the exemplary embodiment is used for forming a film, the oxide semiconductor thin-film is stably producible since the target strength is improved, and further, an influence on TFT characteristics is reducible since the oxide semiconductor thin-film of the exemplary embodiment satisfies the formula (1A). Specifically, an increase in an amount of the X element improves the strength of the sputtering target, however, an excessive increase in the amount of the X element may deteriorate the TFT characteristics. Accordingly, by forming the oxide semiconductor thin-film of the exemplary embodiment using the sputtering target such that the oxide semiconductor thin-film satisfies the formula (1A), an improvement in the target strength and prevention of the deterioration of the TFT characteristics are achievable in good balance.

When X/(In+Sn+Zn+X) of the oxide semiconductor thin-film of the exemplary embodiment is 0.05 or less, the resultant oxide semiconductor thin-film can be easily etched by weak acid such as oxalic acid. Further, deterioration in the TFT characteristics, particularly, a decrease in the mobility can be prevented. X/(In+Sn+Zn+X) of the oxide semiconductor thin-film of the exemplary embodiment is preferably in a range from 0.001 to 0.05, more preferably in a range from 0.003 to 0.03, further preferably in a range from 0.005 to 0.01, particularly preferably in a range from 0.005 to less than 0.01.

It is more preferable that the oxide semiconductor thin-film of the exemplary embodiment satisfies at least one of formulae (2A) to (4A) below representing the atomic ratios of the elements.

0.40≤Zn/(In+Sn+Zn)≤0.80 (2A)

0.15≤Sn/(Sn+Zn)≤0.40 (3A)

0.10≤In/(In+Sn+Zn)≤0.35 (4A)

At Zn/(In+Sn+Zn) being 0.4 or more, a spinel phase is likely to be generated in the oxide semiconductor thin-film, thereby easily achieving the characteristics as the semiconductor. At Zn/(In+Sn+Zn) being 0.80 or less, deterioration in the strength of the oxide semiconductor thin-film, which is caused by abnormal grain growth of a spinel phase, can be prevented. At Zn/(In+Sn+Zn) being 0.80 or less, a decrease in the mobility of the oxide semiconductor thin-film can be prevented. Zn/(In+Sn+Zn) is more preferably in a range from 0.50 to 0.70.

At Sn/(Sn+Zn) being 0.15 or more, deterioration in the strength of the oxide semiconductor thin-film, which is caused by abnormal grain growth of the spinel phase, can be prevented. At Sn/(Sn+Zn) being 0.40 or less, the oxide semiconductor thin-film formed using the sputtering target can be easily etched by weak acid such as oxalic acid. At Sn/(Sn+Zn) being 0.15 or more, an etching speed can be prevented from being excessively high to facilitate controlling the etching. Sn/(Sn+Zn) is more preferably in a range from 0.15 to 0.35.

At In/(In+Sn+Zn) being 0.1 or more, the mobility of the oxide semiconductor thin-film can be prevented from being excessively lowered. At In/(In+Sn+Zn) being 0.35 or less, the film formed by sputtering can be prevented from becoming a conductor to easily achieve the characteristics as the semiconductor. In/(In+Sn+Zn) is more preferably in a range from 0.10 to 0.30.

The oxide semiconductor thin-film of the exemplary embodiment is preferably amorphous when being formed through sputtering, and is preferably kept amorphous after a heat treatment (annealing treatment).

### Thin-Film Transistor

A thin-film transistor of the exemplary embodiment contains the oxide semiconductor thin-film of the exemplary embodiment.

A channel layer of the thin-film transistor is preferably the oxide semiconductor thin-film of the exemplary embodiment.

When the thin-film transistor of the exemplary embodiment has the oxide semiconductor thin-film of the exemplary embodiment as the channel layer, a structure of other elements in the thin-film transistor is not limited to a particular element structure, but any known element structures are usable.

The thin-film transistor of the exemplary embodiment is suitably usable for an electronic device.

Specifically, the thin-film transistor of the invention is suitably applicable to a display such as a liquid crystal display and an organic EL display.

A film thickness of the channel layer in the thin-film transistor of the exemplary embodiment is typically in a range from 10 nm to 300 nm, preferably from 20 nm to 250 nm.

The channel layer in the thin-film transistor of the exemplary embodiment, which is usually used to provide an N-type region, is applicable in combination with various P-type semiconductors (e.g. P-type Si semiconductor, P-type oxide semiconductor, P-type organic semiconductor) to various semiconductor devices such as a PN junction transistor.

The thin-film transistor of the exemplary embodiment is also applicable to various integrated circuits such as a field-effect transistor, logic circuit, memory circuit, and differential amplifier. In addition to the field-effect transistor, the thin-film transistor is applicable to an electrostatic inductive transistor, Schottky barrier transistor, Schottky diode, and resistor.

The thin-film transistor of the exemplary embodiment may be constructed in any manner without limitation and may have known structure such as bottom-gate, bottom-contact, and top-contact structures.

Among the above, the bottom-gate structure is advantageous in view of higher performance than thin-film transistors of amorphous silicon and ZnO. The bottom-gate structure is also preferable for the adaptability in reducing the number of masks during the production process, which results in reduction in the production cost of large-size displays and the like.

The thin-film transistor of the exemplary embodiment is suitably usable for a display.

Channel-etching bottom-gate thin-film transistors are especially preferable for use in large-size displays. The channel-etching bottom-gate thin-film transistors, which require a small number of photomasks in a photolithography process, allow the production of display panels at a low production cost. Especially, channel-etching bottom-gate and channel-etching top-contact thin-film transistors are preferable in terms of excellent performance (e.g. carrier mobility) and industrial applicability.

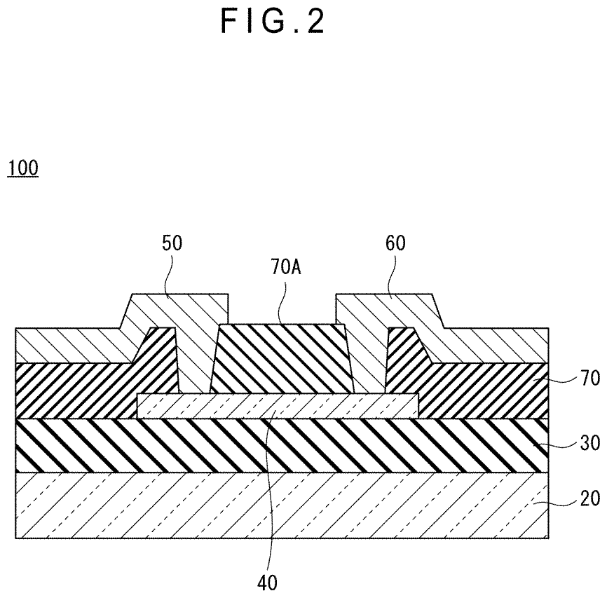

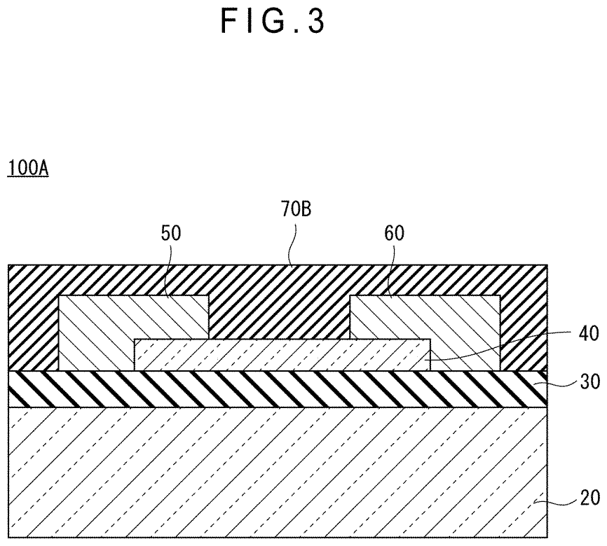

Specific examples of the thin-film transistor are shown in FIGS. 2 and 3.

As shown in FIG. 2, a thin-film transistor 100 includes a silicon wafer 20, a gate insulating film 30, an oxide semiconductor thin-film 40, a source electrode 50, a drain electrode 60, and interlayer insulating films 70, 70A.

The silicon wafer 20 defines a gate electrode. The gate insulating film 30, which is an insulation film for insulation between the gate electrode and the oxide semiconductor thin-film 40, is provided on the silicon wafer 20.

The oxide semiconductor thin-film 40 (channel layer) is provided on the gate insulating film 30. The oxide semiconductor thin-film 40 contains the oxide semiconductor thin-film of the exemplary embodiment.

The source electrode 50 and the drain electrode 60, which are conductive terminals for passing source current and drain current through the oxide semiconductor thin-film 40, are in contact with parts near respective ends of the oxide semiconductor thin-film 40.

The interlayer insulating film 70 is an insulation film for insulating parts other than the contact portions between the source electrode 50 (drain electrode 60) and the oxide semiconductor thin-film 40.

The interlayer insulating film 70A is another insulation film for insulating parts other than the contact portions between the source electrode 50 and drain electrode 60, and the oxide semiconductor thin-film 40. The interlayer insulating film 70A is also an insulation film for insulation between the source electrode 50 and the drain electrode 60, and also serves as a protection layer for the channel layer.

As shown in FIG. 3, the structure of a thin-film transistor 100A is substantially the same as the thin-film transistor 100, except that the source electrode 50 and the drain electrode 60 are in contact with both of the gate insulating film 30 and the oxide semiconductor thin-film 40, and that an interlayer insulating film 70B is integrally provided to cover the gate insulating film 30, the oxide semiconductor thin-film 40, the source electrode 50, and the drain electrode 60.

The material for the drain electrode 60, the source electrode 50 and the gate electrode are not particularly limited but may be selected from generally known materials. In the examples shown in FIGS. 2 and 3, the silicon wafer is used for the substrate. Though the silicon wafer also serves as an electrode, the material of the electrode is not necessarily silicon.

For instance, the electrode may be a transparent electrode made of, for instance, ITO (Indium Tin Oxide), IZO (Indium Zinc Oxide), ZnO, and SnO₂, a metal electrode made of Al, Ag, Cu, Cr, Ni, Mo, Au, Ti, Ta, or the like, a metal electrode made of an alloy containing the above metal elements, or a laminated electrode of layers made of the alloy.

The gate electrode shown in FIGS. 2 and 3 may be formed on a substrate made of glass or the like.

The material for the interlayer insulating films 70, 70A and 70B is not particularly limited but may be selected as desired from generally known materials. Specifically, the interlayer insulating films 70, 70A, 70B may be made of a compound such as SiO₂, SiNₓ, Al₂O₃, Ta₂O₅, TiO₂, MgO, ZrO₂, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, and AlN.

When the thin-film transistor of the exemplary embodiment is a back-channel-etching (bottom-gate) thin-film transistor, it is preferable to provide a protection film on the drain electrode, the source electrode and the channel layer. The protection film enhances the durability against a long-term driving of the TFT. In a top-gate TFT, the gate insulating film is formed on, for instance, the channel layer.

The protection film or the insulation film can be formed, for instance, through a CVD process, which sometimes entails high-temperature treatment. The protection film or the insulation film often contains impurity gas immediately after being formed, and thus is preferably subjected to a heat treatment (annealing). The heat treatment removes the impurity gas to provide a stable protection film or insulation film, and, consequently, highly durable TFT device.

With the use of the oxide semiconductor thin-film of the exemplary embodiment, the TFT device is less likely to be affected by the temperature in the CVD process and the subsequent heat treatment. Accordingly, the stability of the TFT performance can be enhanced even when the protection film or the insulation film is formed.

Among the transistor performance, On/Off characteristics determine display performance of display devices. When the thin-film transistor is used as a switching device of liquid crystal, On/Off ratio is preferably six or more digits. OLED, which is current-driven and whose On-current is of importance, also preferably has six or more digits On/Off ratio.

The thin-film transistor of the exemplary embodiment preferably has On/Off ratio equal to or more than 1×10⁶.

The On/Off ratio can be determined as a ratio [On current value/Off current value] of On current value (a value of Id when Vg=20 V) to Off current value (a value of Id when Vg=−10 V).

The carrier mobility in the TFT of the exemplary embodiment is preferably 5 cm²/Vs or more, more preferably 10 cm²/Vs or more.

The saturation mobility is determined based on a transfer function when a 20 V drain voltage is applied. Specifically, the saturation mobility can be calculated by: plotting a graph of a transfer function Id-Vg; calculating transconductance (Gm) for each Vg; and calculating the saturation mobility using a formula in a saturated region. It should be noted that Id represents a current between the source and drain electrodes, and Vg represents a gate voltage when the voltage Vd is applied between the source and drain electrodes.

A threshold voltage (Vth) is preferably in a range from −3.0 V to 3.0 V, more preferably from −2.0 V to 2.0 V, further preferably from −1.0 V to 1.0 V. At the threshold voltage (Vth) of −3.0 V or more, a thin-film transistor with a high carrier mobility is obtainable. At the threshold voltage (Vth) of 3.0 V or less, a thin-film transistor with small Off current and a large On/Off ratio is obtainable.

The threshold voltage (Vth) is defined as Vg at Id=10⁻⁹ A based on the graph of the transfer function.

The On/Off ratio is preferably in a range from 10⁶ to 10¹², more preferably from 10⁷ to 10¹¹, further preferably from 10⁸ to 10¹⁰. At the On/Off ratio of 10⁶ or more, a liquid crystal display can be driven. At the On/Off ratio of 10¹² or less, an organic EL device with a large contrast can be driven. Further, at the On/Off ratio of 10¹² or less, the off current can be set at 10⁻¹¹ A or less, allowing an increase in image-holding time and improvement in sensitivity when the thin-film transistor is used for a transfer transistor or a reset transistor of a CMOS image sensor.

### Quantum-Tunneling Field-Effect Transistor

The oxide semiconductor thin-film of the exemplary embodiment is usable for a quantum-tunneling Field-Effect Transistor (FET).

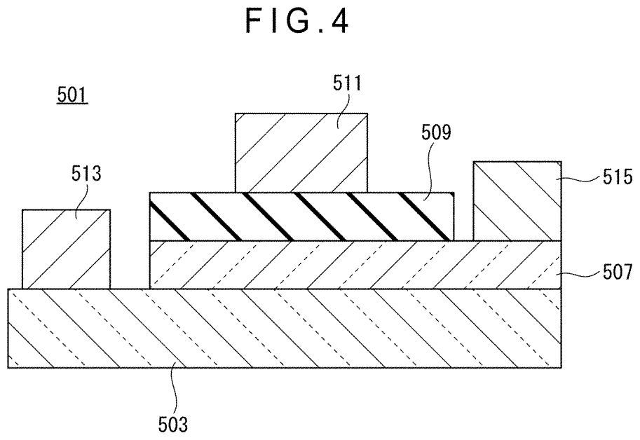

FIG. 4 is a schematic illustration (vertical cross section) of a quantum-tunneling FET (Field-Effect Transistor) according to an exemplary embodiment of the invention.

A quantum-tunneling field-effect transistor 501 includes a p-type semiconductor layer 503, an n-type semiconductor layer 507, a gate insulating film 509, a gate electrode 511, a source electrode 513, and a drain electrode 515.

The p-type semiconductor layer 503, the n-type semiconductor layer 507, the gate insulating film 509, and the gate electrode 511 are layered in this order.

The source electrode 513 is provided on the p-type semiconductor layer 503. The drain electrode 515 is provided on the n-type semiconductor layer 507.

The p-type semiconductor layer 503 is a layer of a p-type IV group semiconductor layer, which is a p-type silicon layer in the exemplary embodiment.

The n-type semiconductor layer 507 is an n-type oxide semiconductor thin-film according to the exemplary embodiment. The source electrode 513 and the drain electrode 515 are conductive films.

Though not shown in FIG. 4, an insulation layer may be provided on the p-type semiconductor layer 503. In this case, the p-type semiconductor layer 503 and the n-type semiconductor layer 507 are connected through a contact hole(s) defined by partially removing the insulation layer. Though not shown in FIG. 4, the quantum-tunneling field-effect transistor 501 may be provided with an interlayer insulating film covering an upper side of the quantum-tunneling field-effect transistor 501.

The quantum-tunneling field-effect transistor 501 is a current-switching quantum-tunneling FET (Field-Effect Transistor) for controlling the electric current tunneled through an energy barrier formed by the p-type semiconductor layer 503 and the n-type semiconductor layer 507 using a voltage applied to the gate electrode 511. With this structure, the band gap of the oxide semiconductor of the n-type semiconductor layer 507 can be increased, thereby decreasing the Off current.

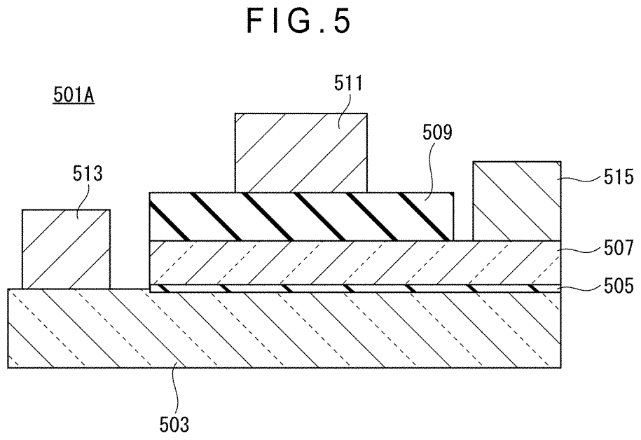

FIG. 5 is a schematic illustration (vertical cross section) of a quantum-tunneling field-effect transistor 501A according to another exemplary embodiment.

The structure of the quantum-tunneling field-effect transistor 501A is the same as the structure of the quantum-tunneling field-effect transistor 501 except that a silicon oxide layer 505 is interposed between the p-type semiconductor layer 503 and the n-type semiconductor layer 507. The off current can be reduced by the presence of the silicon oxide layer.

The thickness of the silicon oxide layer 505 is preferably 10 nm or less. At the thickness of 10 nm or less, the tunnel current securely passes through the energy barrier and the energy barrier can be securely formed with a constant barrier height, preventing the decrease or change in the tunneling current. The thickness of the silicon oxide layer 505 is preferably 8 nm or less, more preferably 5 nm or less, further preferably 3 nm or less, and especially preferably 1 nm or less.

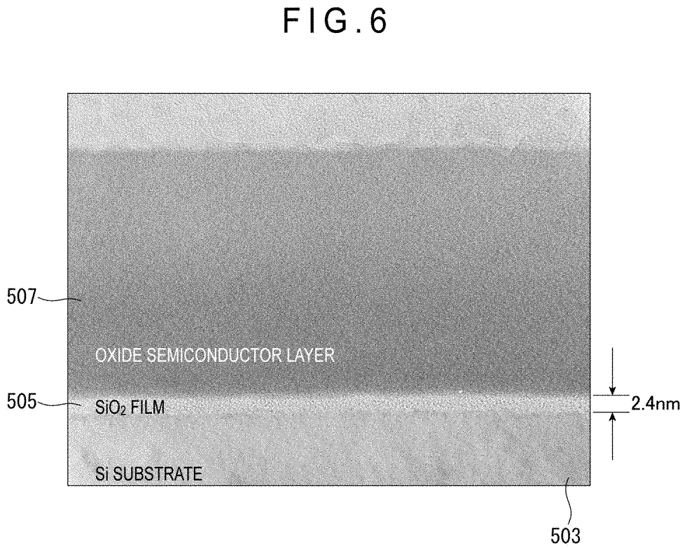

FIG. 6 is a TEM photograph showing the silicon oxide layer 505 between the p-type semiconductor layer 503 and the n-type semiconductor layer 507.

The n-type semiconductor layer 507 in both of the quantum-tunneling field-effect transistors 501 and 501A is an n-type oxide semiconductor.

The oxide semiconductor of the n-type semiconductor layer 507 may be amorphous. Since the oxide semiconductor forming the n-type semiconductor layer 507 is amorphous, the oxide semiconductor can be etched using an organic acid (e.g. oxalic acid) at a large difference in etching rate from the other layer(s), so that the etching process can be favorably performed without any influence on the metal layer (e.g. wiring).

The oxide semiconductor of the n-type semiconductor layer 507 may alternatively be crystalline. The crystalline oxide semiconductor exhibits a larger band gap than the amorphous oxide semiconductor, so that the Off current can be reduced. Further, since the work function can be increased, the control over the current tunneled through the energy barrier formed by the p-type IV group semiconductor material and the n-type semiconductor layer 507 can be facilitated.

A non-limiting example of the production method of the quantum-tunneling field-effect transistor 501 will be described below.

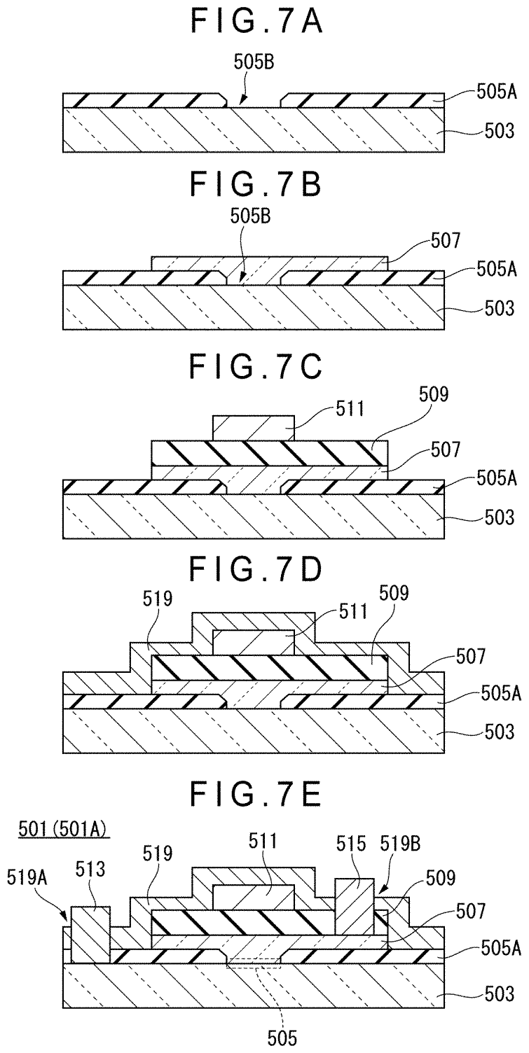

Initially, as shown in FIG. 7A, an insulation film 505A is formed on the p-type semiconductor layer 503. Then, a part of the insulation film 505A is removed by etching or the like to form a contact hole 505B.

Subsequently, as shown in FIG. 7B, the n-type semiconductor layer 507 is formed on the p-type semiconductor layer 503 and the insulation film 505A. At this time, the p-type semiconductor layer 503 and the n-type semiconductor layer 507 are mutually connected through the contact hole 505B.

Subsequently, as shown in FIG. 7C, the gate insulating film 509 and the gate electrode 511 are formed in this order on the n-type semiconductor layer 507.

Then, as shown in FIG. 7D, an interlayer insulating film 519 is formed to cover the insulation film 505A, the n-type semiconductor layer 507, the gate insulating film 509 and the gate electrode 511.

Next, as shown in FIG. 7E, the insulation film 505A on the p-type semiconductor layer 503 and the interlayer insulating film 519 are partially removed to form a contact hole 519A, in which the source electrode 513 is provided.

Further, as shown in FIG. 7E, the gate insulating film 509 on the n-type semiconductor layer 507 and the interlayer insulating film 519 are partially removed to form a contact hole 519B, in which the drain electrode 515 is formed.

The quantum-tunneling field-effect transistor 501 is produced through the above process.

It should be noted that the silicon oxide layer 505 between the p-type semiconductor layer 503 and the n-type semiconductor layer 507 can be formed by applying a heat treatment at a temperature ranging from 150 degrees C. to 600 degrees C. after the n-type semiconductor layer 507 is formed on the p-type semiconductor layer 503. The quantum-tunneling field-effect transistor 501A can be produced through the process including the above additional step.

The thin-film transistor of the exemplary embodiment is preferably a doped-channel thin-film transistor. The doped-channel transistor refers to a transistor whose carrier in the channel is appropriately controlled not by the oxygen vacancy, which is easily affected by an external stimuli such as atmosphere and temperature, but by an n-type doping, for achieving both of high carrier mobility and high reliability.

### Usage of Thin-Film Transistor

The thin-film transistor of the exemplary embodiment is also capable of being embodied as various integrated circuits such as a field-effect transistor, logic circuit, memory circuit, and differential amplifier, which are applicable to electronic devices. Further, the thin-film transistor according to the third exemplary embodiment is also applicable to an electrostatic inductive transistor, Schottky barrier transistor, Schottky diode, and resistor, in addition to the field-effect transistor.

The thin-film transistor of the exemplary embodiment is suitably usable for a display, solid-state image sensor, and the like.

A display and a solid-state image sensor incorporating the thin-film transistor of the exemplary embodiment will be described below.

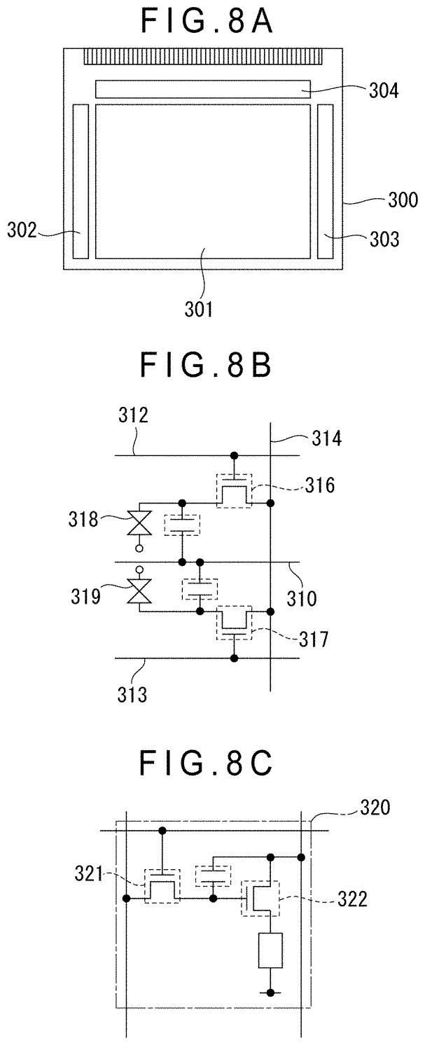

Firstly, a display incorporating the thin-film transistor of the exemplary embodiment will be described with reference to FIG. 8.

FIG. 8A is a top plan view of a display of the exemplary embodiment. FIG. 8B is a circuit diagram showing a circuit of a pixel unit in a form of a liquid crystal device of the display of the exemplary embodiment. FIG. 8B is a circuit diagram showing another circuit of a pixel unit in a form of an organic EL device of the display of the exemplary embodiment.

The transistor in the pixel unit may be the thin-film transistor of the exemplary embodiment. The thin-film transistor of the exemplary embodiment is easily made into an n-channel type. Accordingly, a part of the drive circuit capable of being provided by an n-channel transistor is formed on the same substrate as the transistor of the pixel unit. A highly reliable display can be provided using the thin-film transistor of the exemplary embodiment for the pixel unit and/or the drive circuit.

FIG. 8A is a top plan view showing an example of an active matrix display. The display includes a substrate 300, and a pixel unit 301, a first scan line drive circuit 302, a second scan line drive circuit 303, and a signal line drive circuit 304 formed on the substrate 300. Multiple signal lines extend from the signal line drive circuit 304 to the pixel unit 301. Multiple scan lines extend from the first scan line drive circuit 302 and the second scan line drive circuit 303 to the pixel unit 301. Pixels each including a display element are provided in a matrix at intersections of the scan lines and the signal lines. The substrate 300 of the display is connected to a timing controller (controller, also referred to as a control IC) through a connector such as an FPC (Flexible Printed Circuit).

As shown in FIG. 8A, the first scan line drive circuit 302, the second scan line drive circuit 303, and the signal line drive circuit 304 are provided on the same substrate 300 as the pixel unit 301. Such an arrangement results in reduction in the number of external component (e.g. drive circuit) and, consequently, reduction in production cost. In addition, when the drive circuit is provided outside the substrate 300, the lines have to be extended and the connection between the lines increases. With the drive circuit being provided on the same substrate 300, the number of connections between the lines can be reduced, thereby improving the reliability and yield rate.

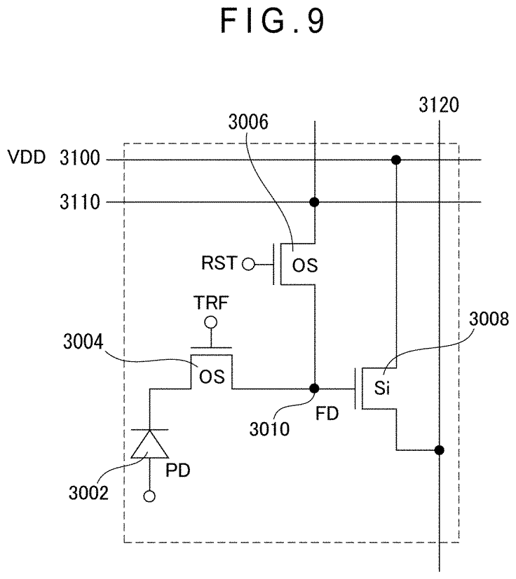

An example of a pixel circuit is shown in FIG. 8B. FIG. 9B shows a circuit of a pixel unit applicable to a pixel unit of a VA liquid crystal display.

The circuit of the pixel unit is applicable to a device having a plurality of pixel electrodes in one pixel. The pixel electrodes are each connected to different transistors, whereby each of the transistors is drivable in accordance with a different gate signal. Thus, the signals to be applied to the respective pixel electrodes of a multi-domain structure can be independently controlled.

A gate line 312 of a transistor 316 and a gate line 313 of a transistor 317 are separated so that different gate signals are inputted thereto. In contrast, a source electrode or drain electrode 314 serving as a data line is common to the transistors 316 and 317. The transistors 316 and 317 may be the transistor of the exemplary embodiment. A highly reliable liquid crystal display can be thereby provided.

First and second pixel electrodes are electrically connected to the transistors 316 and 317, respectively. The first pixel electrode is separated from the second pixel electrode. Shapes of the first and second pixel electrodes are not limited to particular ones. For instance, the first pixel electrode may be V-shaped.

Gate electrodes of the transistors 316 and 317 are connected with the gate lines 312 and 313, respectively. Different gate signals can be inputted to the gate lines 312 and 313 so that the transistors 316 and 317 are operated at different timings, thereby controlling orientation of the liquid crystal.

A capacity line 310, a gate insulating film serving as a dielectric, and a capacity electrode electrically connected with the first pixel electrode or the second pixel electrode may be provided to define a holding capacity.

In a multi-domain structure, first and second liquid crystal devices 318 and 319 are provided in one pixel. The first liquid crystal device 318 includes the first pixel electrode, an opposing electrode, and a liquid crystal layer interposed between the first pixel electrode and the opposing electrode. The second liquid crystal device 319 includes the second pixel electrode, an opposing electrode, and a liquid crystal layer interposed between the second pixel electrode and the opposing electrode.

The pixel unit is not necessarily arranged as shown in FIG. 8B. The pixel unit shown in FIG. 8B may additionally include a switch, a resistor, a capacitor, a transistor, a sensor, and/or a logic circuit.

Another example of the pixel circuit is shown in FIG. 8C. Illustrated is a structure of a pixel unit in a display using an organic EL device.

FIG. 8C illustrates an applicable example of a circuit of a pixel unit 320. In this example, two n-channel transistors are used in one pixel. The oxide semiconductor thin-film of the exemplary embodiment is usable for a channel-formation region in the n-channel transistor. The circuit of the pixel unit can be driven in accordance with digital pulse width modulation control.

A switching transistor 321 and a drive transistor 322 may be the thin-film transistor of the exemplary embodiment. A highly reliable organic EL display can be thereby provided.

The circuit of the pixel unit is not necessarily arranged as shown in FIG. 8C. The circuit of the pixel unit shown in FIG. 8C may additionally include a switch, a resistor, a capacitor, a sensor, a transistor, and/or a logic circuit.

The thin-film transistor of the exemplary embodiment used in a display has been described above.

Next, a solid-state image sensor incorporating the thin-film transistor of the exemplary embodiment will be described with reference to FIG. 9.

CMOS (Complementary Metal Oxide Semiconductor) image sensor is a solid-state image sensor including a signal charge accumulator for retaining an electric potential, and an amplification transistor for transferring (outputting) the electric potential to a vertical output line. When the signal charge accumulator is charged or discharged by a possible leak current from the reset transistor and/or the transfer transistor of the CMOS image sensor, the electric potential of the signal charge accumulator changes. The change in the electric potential of the signal charge accumulator results in the change in the electric potential of the amplification transistor (i.e. shift from a desired value), deteriorating the quality of the captured image.

An effect of the thin-film transistor of the exemplary embodiment incorporated in the reset transistor and transfer transistor of the CMOS image sensor will be described below. The amplification transistor may be any one of the thin-film transistor or a bulk transistor.

FIG. 9 illustrates an exemplary arrangement of the CMOS image sensor. The pixel includes a photodiode 3002 (photoelectric converter), a transfer transistor 3004, a reset transistor 3006, an amplification transistor 3008, and various lines. A plurality of pixels are arranged in a matrix to form the sensor. A selector transistor may be electrically connected to the amplification transistor 3008. The characters in the transistor signs each represent a preferable material to be used for the transistors, where “OS” represents Oxide Semiconductor and “Si” represents silicon. The same applies to the other drawing(s).

The photodiode 3002 is connected to a source of the transfer transistor 3004. A signal charge accumulator 3010 (also referred to as FD (Floating Diffusion)) is provided to a drain of the transfer transistor 3004. The source of the reset transistor 3006 and the gate of the amplification transistor 3008 are connected to the signal charge accumulator 3010. A reset power line 3110 may be omitted in other embodiments. For instance, the drain of the reset transistor 3006 may be connected with a power line 3100 or a vertical output line 3120 instead of the reset power line 3110.

The oxide semiconductor thin-film of the exemplary embodiment, which may be made of the same material as the oxide semiconductor thin-film used for the transfer transistor 3004 and the reset transistor 3006, may be used in the photodiode 3002.

The thin-film transistor of the exemplary embodiment used in a display has been described above.

### EXAMPLES

The invention will be specifically described below with reference to Examples. It should however be noted that the scope of the invention is by no means limited by the Examples.

A sputtering target made of an ITZO oxide sinter containing the X element was produced. Characteristics of the sputtering target made of the ITZO oxide sinter containing the X element was compared with characteristics of the sputtering target made of an ITZO oxide sinter not containing the X element. Specific procedures are as follows.

Firstly, the following powders were weighted so that the starting materials satisfied the respective atomic ratios shown in Table 1.
In starting material: indium oxide powders with a purity of 99.99 mass %
Sn starting material: tin oxide powders with a purity of 99.99 mass %
Zn starting material: zinc oxide powders with a purity of 99.99 mass %
X element: aluminum oxide (Al₂O₃) with a purity of 99.9 mass %, germanium oxide (GeO₂) with a purity of 99.9 mass %, silicon oxide (SiO₂) with a purity of 99.9 mass %, yttrium oxide (Y₂O₃) with a purity of 99.9 mass %, zirconium oxide (ZrO₂) with a purity of 99.9 mass %, magnesium oxide (MgO) with a purity of 99.9 mass %, ytterbium oxide (Yb₂O) with a purity of 99.9 mass %

TABLE 1

| | In/(In + | Sn/(In + | Zn/(In + | | X element |
|---|---|---|---|---|---|
| Sample | Sn + Zn) | Sn + Zn) | Sn + Zn) | | content rate |
| Nos. | (atom %) | (atom %) | (atom %) | X element | (atom %) |
| 1 | 30.0 | 15.0 | 55.0 | Al | 0.1 |
| 2 | 30.0 | 15.0 | 55.0 | Al | 0.5 |
| 3 | 30.0 | 15.0 | 55.0 | Al | 1.0 |
| 4 | 30.0 | 15.0 | 55.0 | Al | 3.0 |
| 5 | 30.0 | 15.0 | 55.0 | Al | 5.0 |
| 6 | 20.0 | 20.0 | 60.0 | Al | 1.0 |
| 7 | 20.0 | 20.0 | 60.0 | Al | 5.0 |
| 8 | 30.0 | 15.0 | 55.0 | Si | 0.1 |
| 9 | 30.0 | 15.0 | 55.0 | Si | 0.5 |
| 10 | 30.0 | 15.0 | 55.0 | Si | 1.0 |
| 11 | 30.0 | 15.0 | 55.0 | Si | 3.0 |
| 12 | 30.0 | 15.0 | 55.0 | Si | 5.0 |
| 13 | 30.0 | 15.0 | 55.0 | Ge | 0.1 |
| 14 | 30.0 | 15.0 | 55.0 | Y | 0.1 |
| 15 | 30.0 | 15.0 | 55.0 | Zr | 0.1 |
| 16 | 30.0 | 15.0 | 55.0 | Mg | 0.1 |
| 17 | 30.0 | 15.0 | 55.0 | Yb | 0.1 |
| 18 | 20.0 | 23.0 | 57.0 | Al | 1.0 |
| 19 | 30.0 | 15.0 | 55.0 | — | 0.0 |
| 20 | 20.0 | 20.0 | 60.0 | — | 0.0 |
| 21 | 20.0 | 23.0 | 57.0 | — | 0.0 |
| 22 | 25.0 | 15.0 | 60.0 | Al | 1.0 |
| 23 | 20.0 | 12.0 | 68.0 | Al | 1.0 |
| 24 | 35.0 | 9.8 | 55.2 | Al | 1.0 |
| 25 | 20.0 | 26.0 | 54.0 | Al | 1.0 |
| 26 | 34.0 | 21.0 | 45.0 | Al | 1.0 |
| 27 | 30.0 | 15.0 | 55.0 | Al | 6.0 |

Next, polyvinyl alcohol was added as a molding binder to the starting materials and mixed with a wet ball mill for 72 hours and pelletized.

Next, the pelletized substance was uniformly fed into a die with an inner diameter of 120 mm×120 mm×7 mm and was press-molded with a cold press machine, and subsequently, was molded at a pressure of 196 MPa with a cold isostatic press machine (CIP). A temperature of the thus obtained molding was raised to 780 degrees C. under oxygen atmosphere at a sintering furnace, and then kept at 780 degrees C. for five hours, further raised to 1400 degrees C., and kept at this temperature (1400 degrees C.) for 20 hours. Subsequently, the sintering furnace was cooled and an oxide sinter was obtained. A rate of temperature increase was 2 degrees C. per minute.

The obtained oxide sinter was cut and surface-polished. A crystal structure of the oxide sinter was examined with an X ray diffraction measurement device (XRD). As a result, with respect to the sample numbers 1 to 17, 19, 20, 22, 23, 24, and 27, existence of a hexagonal laminar compound represented by In₂O₃(ZnO)ₘ (in which m is an integer from 2 to 7) and a spinel compound represented by Zn₂SnO₄ were confirmed. Each of the sample numbers 18 and 21 was a monophase spinel compound represented by Zn₂SnO₄. With respect to the sample numbers 25 and 26, existence of a Bixbyite structure compound and the spinel compound represented by Zn₂SnO₄ were confirmed. Measurement conditions of the XRD are as follows.

Device: Smartlab manufactured by Rigaku Corporation

X-ray: Cu-K α ray (wavelength 1.5418×10⁻¹⁰ m)

Parallel Beam, 2θ-θ Reflection method, Continuous Scan (2.0 degrees/min.)

Sampling interval: 0.02 degrees

Divergence Slit (DS): 1.0 mm

Scattering Slit (SS): 1.0 mm

Receiving Slit (RS): 1.0 mm

The following characteristics of the obtained oxide sinter were measured.

### (1) Average Deflective Strength

The obtained oxide sinter was cut into 30 prismatic test pieces having a rectangular cross section, each of the test pieces having 3 mm thickness×4 mm width×36 mm whole length. The test pieces were measured in terms of three-point flexural strength using a material tester (EZ Graph manufactured by Shimadzu Corporation) in accordance with JIS R 1601:2008. An average of measurement values of the three-point flexural strength of the 30 test pieces was defined as an average deflective strength.

### (2) Relative Density

The relative density of the oxide sinter was measured in accordance with Archimedes' method. Specifically, an aerial weight of the oxide sinter was divided by a volume (=underwater weight/specific gravity of water at a measurement temperature) of the oxide sinter, and the obtained value was represented by percentage and defined as the relative density (unit: %) to a theoretical density p (g/cm³) according to a formula (5).

Relative Density={(aerial weight/volume of oxide sinter)/theoretical density ρ}×100

ρ=(C₁/100/ρ₁+C₂/100/ρ₂ . . . +Cₙ/100/ρₙ)⁻¹ (5)

In the formula (5), each of C₁ to Cₙ represents a content (mass %) of the oxide sinter or a content (mass %) of each of the elements of the oxide sinter. ρ₁ to ρₙ represent densities (g/cm³) of the elements corresponding to C₁ to Cₙ, respectively.

It should be noted that the density of each of the elements is substantially equal to the specific gravity of each of the elements. Accordingly, the value of the specific gravity of oxides described in “Handbook of Chemistry: Pure Chemistry, Chemical Society of Japan, revised 2nd ed. (MARUZEN-YUSHODO Company, Limited) was used as the value of the density.

(3) Bulk Resistivity Value (mΩcm)

A bulk resistivity value, which was an index showing conductivity of the sputtering target, was measured in accordance with a four-probe method (JIS R 1637:1998) using a resistivity meter (product name: Loresta GP MCP-T610 manufactured by Mitsubishi Chemical Corporation). A thickness of the sample was set at 5 mm. The measurement was performed at nine points. An average of measurement values at the nine points was defined as the bulk resistivity value.

Since the oxide sinter had a quadrangular surface in a planar view, the quadrangular surface was divided into nine quadrangles each having an equal area and nine centers of the nine quadrangles were defined as the measurement points.

### (4) Weibull Coefficient

In accordance with a statistical analysis method defined in JIS R 1625:2010, deflective strength was plotted on a Weibull probability axis (hereinafter, referred to as “Weibull plot”). The Weibull coefficient was obtained from an inclination of the Weibull plot.

### (5) Average Crystal Grain Size

The average crystal grain size of the hexagonal laminar compound, the average crystal grain size of the spinel compound, the average crystal grain size of the Bixbyite structure compound were obtained, and an absolute value of a difference among the average crystal grain sizes was obtained. The average crystal grain sizes were measured in the same manner as the method described in the above exemplary embodiments.

### (6) Confirmation of Grains of Hexagonal Laminar Compound

It was determined using SEM-EPMA that the oxide sinter contained grains of the hexagonal laminar compound on a basis of the In element and the Zn element contained in the crystal grain.

### (7) Confirmation of Grains of Spinel Compound

It was determined using SEM-EPMA that the oxide sinter contained grains of the spinel compound on a basis of the Zn element and the Sn element contained in the crystal grain.

### (8) Confirmation of Bixbyite Structure

It was determined using SEM-EPMA that the oxide sinter contained grains of the Bixbyite structure compound when it was found that the crystal grain only contained the In element and oxygen atom, or the crystal grain contained the In element, the Sn element, and oxygen atom in which the In element is 90 atom % or more at an atom % ratio of the In element to the Sn element (In element:Sn element).

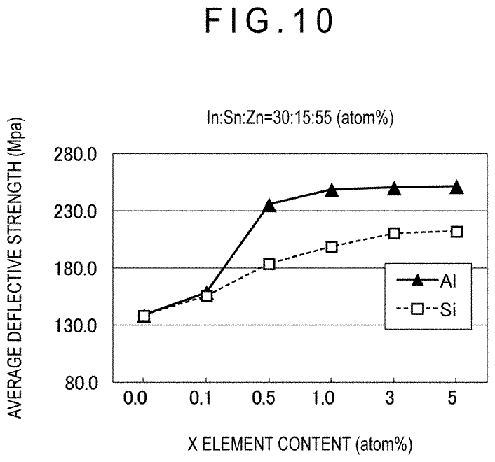

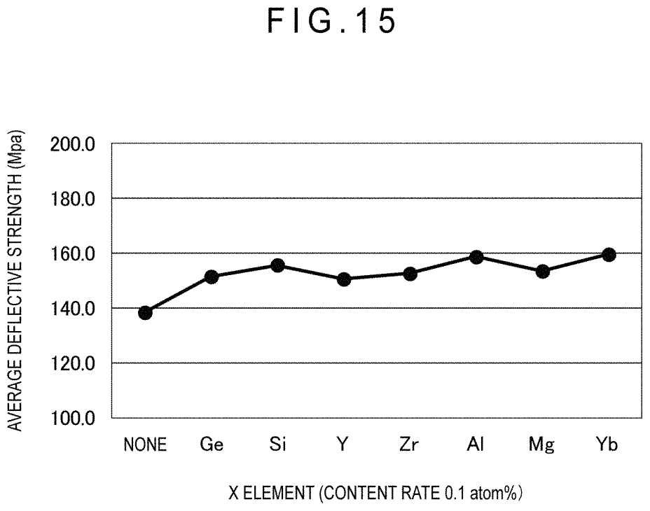

The results are shown in Table 2. FIGS. 10 to 14 show relationships (sample numbers 1 to 5, 8˜12, and 19) between each of the average deflective strength, relative density, bulk resistivity, Weibull coefficient, and average crystal grain size and each of the Al content and the Si content, at In:Sn:Zn=30:15:55 (atom %) in Table 2. FIG. 15 shows a comparison among cases (sample numbers 1, 8, 13 to 17) where the X element was contained at 0.1 atom % in a form of one of Al, Si, G, Si, Y, Mg, and Yb and a case (sample number 19) where no X element was contained.

TABLE 2

| | | | | | | | | d ifference betw een | d ifference betw een |
|---|---|---|---|---|---|---|---|---|---|
| | | | | | | | | average crysta l | average crysta l |
| | | | | | | | | gra in s ize | gra in s ize of B |
| | | X | | | | | | ofhexagonal lam inar | ixby ite structure |
| | | e lem ent | average | | bulk | | average | com pound and | com pound and |
| | | content | deflective | relative | res istiv ity | | crystal | average crysta l | average crysta l |
| Sam ple | X | rate | strength | dens ity | (m Ω | W ebull | gra in s ize | gra in s ize of | gra in s ize |
| Nos. | e lem ent | (atom %) | (M P a ) | (%) | cm ) | coeffic ient | (μm) | spinelcom pound | ofspinelcom pound |
| 1 | A l | 0.1 | 158.7 | 98.6 | 2.69 | 7.1 | 4.8 | ≤1 μm | — |
| 2 | A l | 0.5 | 235.4 | 99.5 | 2.34 | 7.8 | 4.6 | ≤1 μm | — |
| 3 | A l | 1.0 | 248.6 | 99.5 | 2.30 | 13.5 | 4.5 | ≤1 μm | — |
| 4 | A l | 3.0 | 250.2 | 99.6 | 2.13 | 14.6 | 4.3 | ≤1 μm | — |
| 5 | A l | 5.0 | 251.3 | 99.4 | 2.20 | 15.0 | 4.2 | ≤1 μm | — |
| 6 | A l | 1.0 | 252.7 | 99.6 | 2.46 | 12.6 | 4.6 | ≤1 μm | — |
| 7 | A l | 5.0 | 258.5 | 99.5 | 2.53 | 14.1 | 4.4 | ≤1 μm | — |
| 8 | S i | 0.1 | 155.7 | 99.4 | 2.15 | 8.6 | 4.7 | ≤1 μm | — |
| 9 | S i | 0.5 | 183.6 | 99.3 | 2.29 | 9.2 | 4.6 | ≤1 μm | — |
| 10 | S i | 1.0 | 198.6 | 99.5 | 2.20 | 10.3 | 4.4 | ≤1 μm | — |
| 11 | S i | 3.0 | 210.6 | 99.5 | 2.35 | 13.5 | 4.4 | ≤1 μm | — |
| 12 | S i | 5.0 | 211.9 | 99.6 | 2.40 | 13.8 | 4.3 | ≤1 μm | — |
| 13 | G e | 0.1 | 151.5 | 98.0 | 2.17 | 15.2 | 4.8 | ≤1 μm | — |
| 14 | Y | 0.1 | 150.6 | 98.4 | 2.15 | 7.6 | 4.9 | ≤1 μm | — |
| 15 | Z r | 0.1 | 152.6 | 99.1 | 2.55 | 12.4 | 4.7 | ≤1 μm | — |
| 16 | M g | 0.1 | 153.5 | 99.1 | 1.71 | 9.7 | 4.8 | ≤1 μm | — |
| 17 | Y b | 0.1 | 159.6 | 99.4 | 1.89 | 15.2 | 4.7 | ≤1 μm | — |
| 18 | A l | 1.0 | 265.7 | 99.6 | 2.28 | 14.2 | 4.5 | (m onophase | — |
| | | | | | | | | sp ine lcom pound) | |
| 19 | — | 0.0 | 138.4 | 98.4 | 2.63 | 5.9 | 5.5 | >1 μm | — |
| 20 | — | 0.0 | 140.7 | 98.2 | 2.75 | 4.6 | 5.7 | >1 μm | — |
| 21 | — | 0.0 | 145.7 | 99.3 | 2.56 | 6.5 | 20.5 | (m onophase | — |
| | | | | | | | | sp ine lcom pound) | |
| 22 | A l | 1.0 | 254.3 | 99.7 | 2.21 | 15.6 | 4.1 | ≤1 μm | — |
| 23 | A l | 1.0 | 246.3 | 99.5 | 2.34 | 13.4 | 4.5 | ≤1 μm | — |
| 24 | A l | 1.0 | 269.7 | 99.8 | 2.11 | 15.5 | 4.7 | ≤1 μm | — |
| 25 | A l | 1.0 | 246.2 | 99.7 | 2.13 | 14.3 | 4.5 | — | ≤1 μm |
| 26 | A l | 1.0 | 256.0 | 99.5 | 2.24 | 15.7 | 4.6 | — | ≤1 μm |
| 27 | A l | 6.0 | 255.6 | 99.8 | 2.51 | 14.2 | 4.3 | ≤1 μm | — |

As shown in Table 2, the samples containing the X element (sample numbers 1 to 18, 22 to 27) had a larger average deflective strength, a larger Weibull coefficient and a smaller average crystal grain size than those of the samples containing no X element (sample numbers 19, 20, 21)

With respect to the bulk resistivity, the samples containing the X element (sample numbers 1 to 18, 22 to 27) were substantially at the same level as or slightly smaller than the samples containing no X element (sample numbers 19, 20, 21).

With respect to the relative density, the samples containing the X element (sample numbers 1 to 18, 22 to 27) were substantially at the same level as the samples containing no X element (sample numbers 19, 20, 21).

Specifically, the sample containing the X element (sample numbers 1 to 18, 22 to 27) had the average deflective strength of 150 MPa or more, the bulk resistivity of 2.69 mΩcm or less, Weibull coefficient of 7 or more, and the average crystal grain size of 10 μm or less.

In the sample containing the X element (sample numbers 1 to 17, 22 to 24), a difference between the average crystal grain size of the hexagonal laminar compound and the average crystal grain size of the spinel compound was 1 μm or less. Moreover, in the sample containing the X element (sample numbers 25, 26), a difference between the average crystal grain size of the Bixbyite structure compound and the average crystal grain size of the spinel compound was 1 μm or less. In the sample containing no X element (sample numbers 1 to 19, 20), the difference between the average crystal grain size of the hexagonal laminar compound and the average crystal grain size of the spinel compound exceeded 1 μm. This result revealed that, by containing the X element, the oxide sinter was obtained such that the average deflective strength and the Weibull coefficient were large and the bulk resistivity, the relative density, and the average crystal grain size fell within a favorable range.

As shown in FIG. 10, in a comparison among a plurality of samples in which In, Sn, and Zn contents were fixed and Al (X element) content was different, the average deflective strength was increased as the Al content was increased, but the increase in the average deflective strength became mild when the Al content exceeded 0.5 atom %.

Moreover, as shown in FIG. 10, in a comparison among a plurality of samples in which In, Sn, and Zn contents were fixed and Si (X element) content was different, the average deflective strength was also increased as the Si content was increased. In a comparison among the samples in which the X element was contained at the same amount, the samples containing Al exhibited a larger average deflective strength than the samples containing Si.

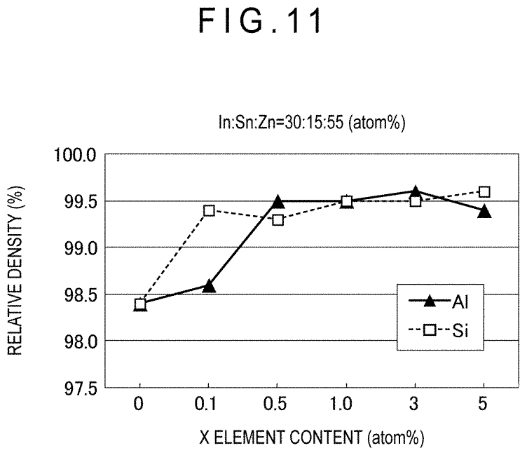

As shown in FIG. 11, in a comparison among a plurality of samples in which In, Sn, and Zn contents were fixed and Al (X element) content was different, the relative density was also increased as the Al content was increased, but the increase in the relative density was saturated when the Al content exceeded 0.5 atom %.

Moreover, as shown in FIG. 11, in a comparison among a plurality of samples in which In, Sn, and Zn contents were fixed and Si (X element) content was different, the relative density was also increased as the Si content was increased, but the increase in the relative density was saturated when the Si content exceeded 0.1 atom %.

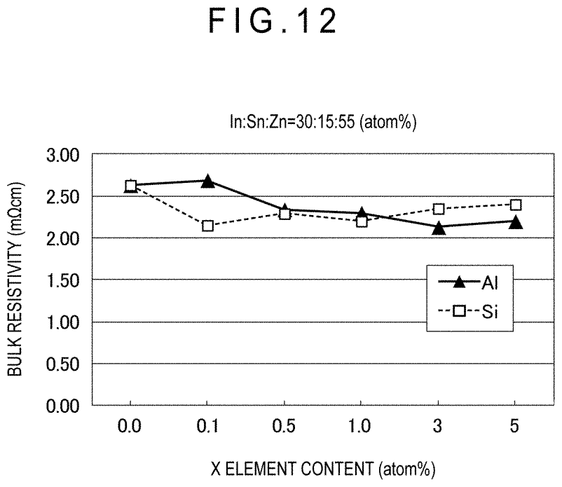

As shown in FIG. 12, in a comparison among a plurality of samples in which In, Sn, and Zn contents were fixed and Al (X element) content was different, the bulk resistivity was decreased as the Al content was increased.

Moreover, as shown in FIG. 12, in a comparison among a plurality of samples in which In, Sn, and Zn contents were fixed and Si (X element) content was different, the bulk resistivity was decreased as the Si content was increased, but slightly increased when the Si content exceeded 3 atom %.

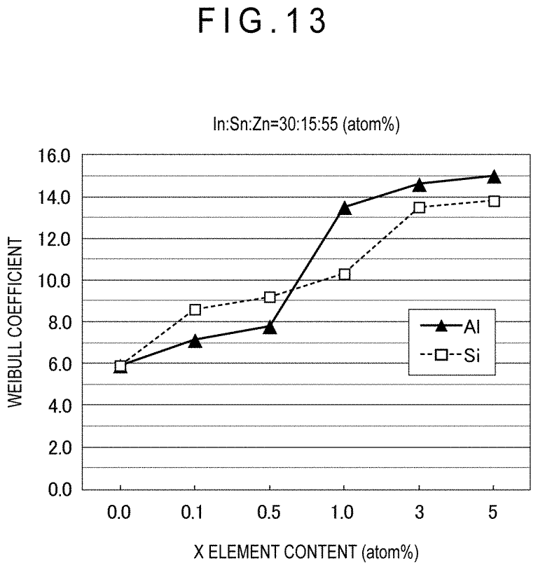

As shown in FIG. 13, in a comparison among a plurality of samples in which In, Sn, and Zn contents were fixed and Al (X element) content was different, the Weibull coefficient was increased as the Al content was increased, but the increase in the Weibull coefficient was saturated when the Al content exceeded 3 atom %.

Moreover, as shown in FIG. 13, in a comparison among a plurality of samples in which In, Sn, and Zn contents were fixed and Si (X element) content was different, the Weibull coefficient was increased as the Si content was increased, but the increase in the Weibull coefficient was saturated when the Si content exceeded 3 atom %.

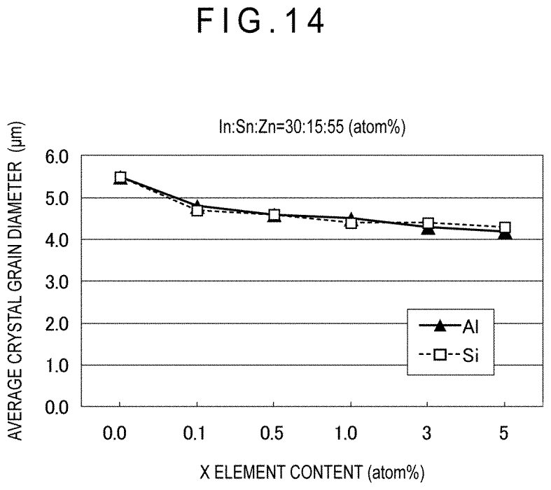

As shown in FIG. 14, in a comparison among a plurality of samples in which In, Sn, and Zn contents were fixed and Al (X element) content was different, the average crystal grain size was decreased as the Al content was increased.

Moreover, as shown in FIG. 14, in a comparison among a plurality of samples in which In, Sn, and Zn contents were fixed and Si (X element) content was different, the average crystal grain size was decreased as the Si content was increased.

The samples containing Al and the samples containing Si were substantially at the same level with respect to the average crystal grain size.

As shown in FIG. 15, in a comparison among a plurality of samples in which the respective contents of In, Sn, Zn and X element were fixed but a type of the X element was different, and a sample containing no X element, the samples containing the X element exhibited a larger average deflective strength than the sample containing no X element.

### Production of Thin-Film Transistor

A thin-film transistor was produced according to a process below.

### (1) Film-Formation Step

The oxide sinters with the sample numbers were ground and polished to produce 4-inch diameter×5 mm-thick sputtering targets. Specifically, the ground and polished oxide sinters were respectively bonded to backing plates to produce the sputtering targets. A bonding rate of each of the sputtering targets was 98% or more. At the bonding of the oxide sinters to the respective backing plates, no crack was generated on the oxide sinters, so that the sputtering targets were favorably produced. Each bonding rate was checked by X-ray CT.

A 50-nm thin film (oxide semiconductor layer) was formed on a silicon wafer 20 (gate electrode) coated with a thermally oxidized film (gate insulating film) through sputtering via a metal mask using each of the produced sputtering targets under the film-formation conditions shown in Table 3. At this time, sputtering gas in a form of mixture gas of high-purity argon and 20% high-purity oxygen was used for sputtering. During the sputtering, no crack was generated on the sputtering targets.

### (2) Formation of Source/Drain Electrodes

Next, source/drain electrodes in a form of titanium electrodes were formed through sputtering of titanium metal using a metal mask with a pattern corresponding to contact holes for the source/drain. L/W of a channel portion was set at 200 μm/1000 μm. The obtained laminates were heated in atmospheric air at 350 degrees C. for 60 minutes to produce thin-film transistors before the protective insulation film was formed.

TABLE 3

| | | |
|---|---|---|
| Film-formation | Atmosphere gas | Ar + O₂ |
| conditions of | Back pressure before film formation (Pa) | 2 × 10⁻⁴ |
| semiconductor | Sputter pressure at film formation (Pa) | 0.5 |
| film | Substrate temperature at film formation | 25 |
| | (° C.) | |
| | Oxygen partial pressure at film formation | 20 |
| | (%) | |
| Heating condition | Heating after film formation: temperature | 350 |
| after formation | (° C.) | |
| of semiconductor | : temperature increase rate (° C./min) | 10 |
| film | : time (min) | 60 |
| | : atmosphere | air |

The produced thin-film transistors (TFT No. A1 to A27) were evaluated as follows. The results are shown in Table 4.

### Crystal Characteristics of Semiconductor Film

On the oxide semiconductor thin-films formed on the respective silicon wafers, the crystallinity of the films without being heated after the films were formed by sputtering (immediately after being deposited) and the films heated after film-formation were measured and evaluated through XRD (X-Ray Diffraction). Then, it was found that the films were amorphous both before and after being heated.

### Performance Evaluation of TFT

Saturation mobility, S value and threshold voltage were evaluated. The results are shown in “TFT properties after heat treatment and before formation of SiO₂ film” in Table 4.

The saturation mobility was determined based on a transfer function when 20 V drain voltage was applied. Specifically, the saturation mobility was calculated by: plotting a graph of a transfer function Id-Vg; calculating transconductance (Gm) for each Vg; and calculating the saturation mobility using a formula in a linear region. It should be noted that Gm is represented by ∂(Id)/∂(Vg), and the saturation mobility is defined by a maximum carrier mobility in a Vg range from −15 to 25 V. The saturation mobility herein is evaluated according to the above unless otherwise specified. In the above, Id represents a current between source and drain electrodes, and Vg represents a gate voltage when the voltage Vd is applied between the source and drain electrodes.

The S value represents a difference between the gate voltages when the drain current is changed from 10 pA to 100 pA.

The threshold voltage (Vth) is defined as Vg at Id=10−9 A based on the graph of the transfer function.

Further, the oxide semiconductor layers of the obtained TFT samples were analyzed using an ICP-AES (Inductively Coupled Plasma-Atomic Emission Spectrometer, manufactured by Shimadzu Corporation). As a result, it was found that the atomic ratios of the obtained oxide semiconductor thin-films were the same as the atomic ratios of the oxide sinters used for producing the oxide semiconductor thin-films.

TABLE 4

| | Oxide sinter used for | | | | | |
|---|---|---|---|---|---|---|
| | sputtering target | | | TFT characteristics | | |
| | Sam- | | X element | | S | |
| TFT | ple | X | content rate | Mobility | value | Vth |
| Nos. | Nos. | element | (atom %) | (cm²/vs) | (V/dec) | (V) |
| A1 | 1 | Al | 0.1 | 24 | 0.2 | 0.4 |
| A2 | 2 | Al | 0.5 | 23 | 0.1 | 0.6 |
| A3 | 3 | Al | 1.0 | 23 | 0.1 | 0.9 |
| A4 | 4 | Al | 3.0 | 21 | 0.2 | 0.9 |
| A5 | 5 | Al | 5.0 | 20 | 0.2 | 1.5 |
| A6 | 6 | Al | 1.0 | 19 | 0.1 | 0.8 |
| A7 | 7 | Al | 5.0 | 17 | 0.2 | 1.5 |
| A8 | 8 | Si | 0.1 | 24 | 0.1 | 0.2 |
| A9 | 9 | Si | 0.5 | 23 | 0.2 | 0.5 |
| A10 | 10 | Si | 1.0 | 22 | 0.1 | 0.8 |
| A11 | 11 | Si | 3.0 | 22 | 0.1 | 0.9 |
| A12 | 12 | Si | 5.0 | 21 | 0.1 | 1.2 |
| A13 | 13 | Ge | 0.1 | 25 | 0.2 | 0.2 |
| A14 | 14 | Y | 0.1 | 25 | 0.2 | 0.3 |
| A15 | 15 | Zr | 0.1 | 24 | 0.1 | 0.3 |
| A16 | 16 | Mg | 0.1 | 24 | 0.1 | 0.2 |
| A17 | 17 | Yb | 0.1 | 24 | 0.2 | 0.4 |
| A18 | 18 | Al | 1.0 | 21 | 0.1 | 0.8 |
| A19 | 19 | — | 0.0 | 26 | 0.2 | 0.2 |
| A20 | 20 | — | 0.0 | 23 | 0.2 | 0.1 |
| A21 | 21 | — | 0.0 | 23 | 0.1 | 0.2 |
| A22 | 22 | Al | 1.0 | 20 | 0.1 | 0.6 |
| A23 | 23 | Al | 1.0 | 18 | 0.1 | 0.5 |
| A24 | 24 | Al | 1.0 | 26 | 0.1 | 0.5 |
| A25 | 25 | Al | 1.0 | 18 | 0.2 | 0.4 |
| A26 | 26 | Al | 1.0 | 25 | 0.2 | 0.3 |
| A27 | 27 | Al | 6.0 | 16 | 0.2 | 2.3 |

Table 4 revealed that the mobility was lowered and the threshold voltage (Vth) was shifted to the positive as the added amount of the X element with respect to indium was increased.

### INDUSTRIAL APPLICABILITY

A sputtering target of the invention is usable for forming an oxide semiconductor layer of a thin-film transistor for driving a display such as a liquid crystal display or an organic EL display. Moreover, the sputtering target of the invention is usable for producing a transparent conductive film applied to a light receiving element, a display element, an electrode of a touch panel, an antifogging transparent heating element, or the like.

### EXPLANATION OF CODES

1: oxide sinter
3: backing plate
20: silicon wafer
30: gate insulating film
40: oxide semiconductor thin-film
50: source electrode
60: drain electrode
70: interlayer insulating film
70A: interlayer insulating film
70B: interlayer insulating film
100: thin-film transistor
100A: thin-film transistor
300: substrate
301: pixel unit
302: first scan line drive circuit
303: second scan line drive circuit
304: signal line drive circuit
310: capacity line
312: gate line
313: gate line
314: drain electrode
316: transistor
317: transistor
318: first liquid crystal device
319: second liquid crystal device
320: pixel unit
321: switching transistor
322: drive transistor
3002: photodiode
3004: transfer transistor
3006: reset transistor
3008: amplification transistor
3010: signal charge accumulator
3100: power line
3110: reset power line
3120: vertical output line

1. A sputtering target comprising an oxide sinter comprising indium (In) element, tin (Sn) element, zinc (Zn) element, X element and oxygen, the oxide sinter comprising a spinel structure compound represented by Zn₂SnO₄ and satisfying a formula (1) representing an atomic ratio of the elements,
0.001≤X/(In+Sn+Zn+X)≤0.05 (1)
where: In, Zn, Sn, and X represent contents of the In element, Zn element, Sn element, and X element in the oxide sinter, respectively, and the X element is at least one element selected from Ge, Si, Y, Zr, Al, Mg, Yb and Ga.

2. The sputtering target according to claim 1, wherein the atomic ratio represented by the formula (1) of the oxide sinter is in a range from 0.003 to 0.03.

3. The sputtering target according to claim 1, wherein the oxide sinter satisfies a formula (2) below,
0.40≤Zn/(In+Sn+Zn)≤0.80 (2).

4. The sputtering target according to claim 1, wherein the oxide sinter satisfies a formula (3) below,
0.15≤Sn/(Sn+Zn)≤0.40 (3).

5. The sputtering target according to claim 1, wherein the oxide sinter satisfies a formula (4) below,
0.10≤In/(In+Sn+Zn)≤0.35 (4).

6. The sputtering target according to claim 1, wherein the oxide sinter comprises a hexagonal laminar compound represented by In₂O₃(ZnO)ₘ in which m is in a range from 2 to 7.

7. The sputtering target according to claim 1, wherein the oxide sinter exhibits an average deflective strength of 150 MPa or more.

8. The sputtering target according to claim 1, wherein a Weibull coefficient of an average deflective strength of the oxide sinter is 7 or more.

9. The sputtering target according to claim 1, wherein
the oxide sinter has an average crystal grain size of 10 μm or less, and
a difference between an average crystal grain size of a hexagonal laminar compound and an average crystal grain size of the spinel structure compound is 1 μm or less.

10. The sputtering target according to claim 1, wherein
the oxide sinter has an average crystal grain size of 10 μm or less, and
a difference between an average crystal grain size of a Bixbyite structure compound and an average crystal grain size of the spinel structure compound is 1 μm or less.

11. An oxide semiconductor thin-film comprising indium (In) element, tin (Sn) element, zinc (Zn) element, X element and oxygen, and satisfying a formula (1A) representing an atomic ratio of the elements,
0.001≤X/(In+Sn+Zn+X)≤0.05 (1A)
where: In, Zn, Sn, and X represent contents of the In element, Zn element, Sn element, and X element in the oxide semiconductor thin-film, respectively, and the X element is at least one element selected from Ge, Si, Y, Zr, Al, Mg, Yb and Ga.

12. A thin-film transistor comprising the oxide semiconductor film according to claim 11.

13. An electronic device comprising the thin-film transistor according to claim 12.

14. The sputtering target according to claim 2, wherein the oxide sinter satisfies a formula (2) below,
0.40≤Zn/(In+Sn+Zn)≤0.80 (2).

15. The sputtering target according to claim 2, wherein the oxide sinter satisfies a formula (3) below,
0.15≤Sn/(Sn+Zn)≤0.40 (3).

16. The sputtering target according to claim 3, wherein the oxide sinter satisfies a formula (3) below,
0.15≤Sn/(Sn+Zn)≤0.40 (3).

17. The sputtering target according to claim 2, wherein the oxide sinter satisfies a formula (4) below,
0.10≤In/(In+Sn+Zn)≤0.35 (4).

18. The sputtering target according to claim 3, wherein the oxide sinter satisfies a formula (4) below,
0.10≤In/(In+Sn+Zn)≤0.35 (4).

19. The sputtering target according to claim 4, wherein the oxide sinter satisfies a formula (4) below,
0.10≤In/(In+Sn+Zn)≤0.35 (4).
